(19) United States
(12) Patent Application Publication
(10) Pub. No.: US 2012/0241769 A1
(43) Pub. Date: Sep. 27, 2012

(54) PHOTODIODE AND MANUFACTURING METHOD FOR SAME, SUBSTRATE FOR DISPLAY PANEL, AND DISPLAY DEVICE

(75) Inventor: Sumio Katoh, Osaka (JP)

(73) Assignee: SHARP KABUSHIKI KAISHA, Osaka (JP)

(21) Appl. No.: 13/511,969

(22) PCT Filed: Jul. 16, 2010
(86) PCT No.: PCT/JP2010/062094

§ 371 Date: May 24, 2012

(30) Foreign Application Priority Data
Nov. 27, 2009 (JP) 2009-270818

(51) Int. Cl. H01L 31/105; H01L 31/18; H01L 27/146

(52) U.S. Cl. 257/84; 257/458; 438/87; 257/E31.061; 257/E27.13; 257/E31.126; 257/E31.032

(57) ABSTRACT

A third semiconductor layer 14 is formed on a light receiving surface 13a of a second semiconductor layer 13 so as to cover the light receiving surface 13a of the second semiconductor layer 13 at least partially in a plan view. A first semiconductor layer 10 is formed on an opposite surface of the light receiving surface 13a of the second semiconductor layer 13 so as to overlap the light receiving surface 13a and the third semiconductor layer 14 at least partially in a plan view. In the second semiconductor layer 13, the relative light receiving sensitivity to respective wavelengths of light has the highest value at a wavelength in an infrared region. Thus, even if the intensity of light of the infrared region that is emitted to an object of detection is not increased when sensing by a photodiode is performed using light of the infrared range, it is possible to achieve a photodiode that has a high S/N ratio, which is a ratio of data of received light with respect to noise, and that has high detection accuracy.

### TECHNICAL FIELD

The present invention relates to a photodiode (optical sensor), a method of manufacturing the photodiode, a display panel substrate having the photodiode, and a display device having this display panel substrate.

### BACKGROUND ART

In recent years, a display device in which an optical sensor is provided in a display region of the display device having a plurality of pixels and in a peripheral region that is a region in a periphery of the display region has been developed. Furthermore, the optical sensor can be manufactured in the process of manufacturing pixel TFT elements provided in the display region and driver TFT elements provided in the peripheral region for driving the pixel TFT element.

In addition to a normal display function, this display device can have a touch panel function in which when an input pen, a finger of a person, or the like touches a surface of the display device, for example, the touched position can be detected using a function of the optical sensor to detect an amount of light and the like.

Further, as the optical sensor provided in the display device, there is a PIN photodiode, for example. As configurations of the PIN photodiode, there are a multilayer configuration (vertical configuration) in which a P layer, an I layer (light receiving portion), and an N layer are laminated in this order with respect to a substrate and a horizontal configuration (lateral configuration) in which the P layer, the I layer (light receiving portion), and the N layer are arranged in an in-plane direction on a substrate. Here, the P layer is a semiconductor layer that has a high concentration of a P-type impurity. The I layer (light receiving portion) is either an intrinsic semiconductor layer or a semiconductor layer that has a low impurity concentration. The N layer is a semiconductor layer that has a high concentration of an N-type impurity.

Patent Document 1 describes an image sensor that uses the PIN photodiode of a multilayer configuration as the optical sensor, for example.

FIG. 21 is a schematic cross-sectional view of the image sensor that uses the PIN photodiode of the multilayer configuration as the optical sensor.

As shown in the figure, in an optical sensor formation region of the image sensor, an N-type polycrystalline silicon layer is formed on a substrate 101 formed of quartz glass as a lower electrode 102 of an amorphous silicon photodiode 103.

The amorphous silicon photodiode 103 has a PIN photodiode configuration of a multilayer configuration in which a P-type amorphous silicon carbide layer doped with B, an intrinsic amorphous silicon layer, and an N-type amorphous silicon carbide layer doped with P are laminated in this order. Furthermore, on the N-type amorphous silicon carbide layer, an ITO (Indium Tin Oxide) electrode 104 is formed as an upper electrode of the amorphous silicon photodiode 103.

On the other hand, in a thin film transistor (hereinafter, TFT) formation region of the image sensor, a polycrystalline silicon layer having a source portion 106, a channel portion 107, and a drain portion 108 is formed on the substrate 101 formed of quartz glass. Furthermore, on the polycrystalline silicon layer, a gate insulating film 109 is formed. On the gate insulating film 109, a gate electrode 110 that is the same layer as the lower electrode 102 of the above-mentioned amorphous silicon photodiode 103 is formed. Furthermore, on an interlayer insulating film 111 that is formed so as to cover the substrate 101, the gate insulating film 109, the gate electrode 110, and the above-mentioned polycrystalline silicon layer, a wiring line member 105 formed of Al is formed.

According to the configuration above, the lower electrode 102 of the amorphous silicon photodiode 103 is formed of the N-type polycrystalline silicon layer. Because of this, it is possible to suppress a dark current compared to a configuration that uses a metal such as chromium as the lower electrode 102.

Further, when a metal is used as the lower electrode 102, the lower electrode 102 is likely to react to the above-mentioned amorphous silicon, thereby causing a problem of lowering the heat resistance of the device. However, when the N-type polycrystalline silicon layer is used as the lower electrode 102 as in the configuration above, the heat resistance of the device can be improved.

Furthermore, when a metal is used as the lower electrode 102, a high level of stress may be applied to the device due to a difference in coefficient of thermal expansion of other materials such as the amorphous silicon, for example. As a result, the reliability of the device may be lowered, and the manufacturing yield may be reduced. However, it has been explained that an occurrence of the stress can be prevented by using the N-type polycrystalline silicon layer as the lower electrode 102.

FIG. 22 is a schematic cross-sectional view of a conventional optical sensor having a PIN photodiode of a lateral configuration.

As shown in the figure, on a substrate 201, a first conductive layer 202 formed of a metal such as chromium, for example, is formed as a light shielding layer to block light entering a semiconductor layer 204, which is described later, from the substrate 201 side. A first insulating layer 203 is formed so as to cover the substrate 201 and the first conductive layer 202. A semiconductor layer 204 formed of polycrystalline silicon is formed on the first insulating layer 203.

The semiconductor layer 204 is formed such that an intrinsic polycrystalline silicon layer 204i is disposed between a P-type polycrystalline silicon layer 204p doped with B and an N-type polycrystalline silicon layer 204n doped with P.

Further, a second insulating layer 205 is formed so as to cover the first insulating layer 203 and the semiconductor layer 204.

Patent Document 2 describes a display device in which an optical sensor having the PIN photodiode of the lateral configuration shown in FIG. 22 and a pixel switching element are formed in the same process.

Furthermore, Patent Document 2 also describes a display device in which an optical sensor that has a PIN photodiode of a lateral configuration in which two semiconductor layers formed of different materials are laminated and a pixel switching element are formed in the same process.

FIG. 23 is a schematic cross-sectional view of a conventional display device that has a PIN photodiode of a lateral configuration in which two semiconductor layers formed of different materials are laminated.

As shown in the figure, an optical sensor 300a having the PIN photodiode of the lateral configuration has a first semiconductor layer 304 and a second semiconductor layer 305.

On a substrate 301, a control electrode 302 is formed, and an insulating layer 303 is formed so as to cover the substrate 301 and the control electrode 302.

The first semiconductor layer 304 is formed such that an intrinsic silicon layer 304i formed on the insulating layer 303 at a portion corresponding to the control electrode 302 is disposed between a P-type silicon layer 304p and an N-type silicon layer 304n.

Here, a semiconductor layer 304a provided in a pixel switching element 300b that is constituted of a gate electrode 302G, the insulating layer 303, the semiconductor layer 304a, an interlayer insulating film 306, a source electrode 307S, and a drain electrode 307D is formed of the same layer as the first semiconductor layer 304 provided in the optical sensor 300a.

On the other hand, as shown in the figure, the second semiconductor layer 305 provided in the optical sensor 300a is formed on a planarized portion of the first semiconductor layer 304 that includes a light receiving portion.

The second semiconductor layer 305 is formed of silicon and germanium so as to have a narrower band gap than the first semiconductor layer 304.

Patent Document 2 explains that, according to the configuration above, the carrier mobility can be improved because distortion is given in the second semiconductor layer 305 and that data of received light can be generated in the optical sensor 300a in a highly sensitive manner. In addition, it is explained that it is possible to prevent an occurrence of a leakage current in the pixel switching element 300b.

Further, it is explained that, according to the configuration above, an S/N ratio, which is a ratio of data of received light obtained by the optical sensor 300a with respect to noise, can be improved.

### RELATED ART DOCUMENTS

### Patent Documents

Patent Document 1: Japanese Patent Application Laid-Open Publication, “Japanese Patent Application Laid-Open Publication No. H5-136386 (Published on Jun. 1, 1993)”
Patent Document 2: Japanese Patent Application Laid-Open Publication, “Japanese Patent Application Laid-Open Publication No. 2009-139565 (Published on Jun. 25, 2009)”
Patent Document 3: Japanese Patent Application Laid-Open Publication, “Japanese Patent Application Laid-Open Publication No. H11-40841 (Published on Feb. 12, 1999)”
Patent Document 4: Japanese Patent Application Laid-Open Publication, “Japanese Patent Application Laid-Open Publication No. 2005-72126 (Published on Mar. 17, 2005)”

### SUMMARY OF THE INVENTION

### Problems to be Solved by the Invention

When using an optical sensor that receives visible light to detect an object of detection, data of received light obtained by the optical sensor includes a large amount of noises due to effects of visible light that is contained in external light. When a display device that has the above-mentioned optical sensor performs black display or the like, visible light that is emitted from the display device to irradiate the object of detection and that is reflected by the object of detection is absent (thereby the detection must depend on external light only). Because of this, it is difficult to detect a position of the object of detection in an accurate manner.

Thus, light near a wavelength of 850 nm (infrared region) is typically emitted to an object of detection such as a finger or the like placed on a display surface of the display device. The optical sensor receives light near a wavelength of 850 nm (infrared region) that is reflected by the object of detection to detect the position where the object of detection is placed.

In a configuration of Patent Document 1, a PIN photodiode of a multilayer configuration is used as the optical sensor. Its light receiving portion is formed of an intrinsic amorphous silicon layer.

FIG. 24 shows a relative sensitivity (spectral sensitivity characteristics) of amorphous silicon (a-Si) to the respective wavelengths.

As shown in the figure, the relative sensitivity of the amorphous silicon (a-Si) to the respective wavelengths is relatively high in a visible light region. However, near a wavelength of 850 nm (infrared region), which is typically used for sensing in an optical sensor, the relative sensitivity becomes significantly low.

Therefore, in the optical sensor having an intrinsic amorphous silicon layer as the light receiving portion described in Patent Document 1, it is difficult to achieve an optical sensor that has high detection accuracy (S/N ratio, which is a ratio of data of received light with respect to noise) unless the intensity of light near a wavelength of 850 nm (infrared region) that is emitted to the object of detection is increased. However, in order to increase the intensity of the above-mentioned light, the amount of light of a backlight that emits visible light and infrared light near the wavelength of 850 nm in planar shapes needs to be increased. As a result, the amount of visible light emitted as planar light is also increased, thereby negatively affecting the display state of the display device.

FIG. 25 shows a relative sensitivity (spectral sensitivity characteristics) of polycrystalline silicon (Poly-Si) to the respective wavelengths.

As shown in the figure, the relative sensitivity of the polycrystalline silicon (Poly-Si) to the respective wavelengths is relatively high in the visible light region in a manner similar to that of the relative sensitivity of the above-mentioned amorphous silicon (a-Si) to the respective wavelengths. However, near the wavelength of 850 nm (infrared region), which is typically used for sensing in the optical sensor, the relative sensitivity becomes significantly low.

Because of this, it is also difficult to achieve an optical sensor that has high detection accuracy in the optical sensor that uses the intrinsic polycrystalline silicon layer 204i as the light receiving portion shown in FIG. 22 unless the intensity of light near a wavelength of 850 nm (infrared region) that is emitted to the object of detection is increased.

On the other hand, in the configuration of Patent Document 2, as shown in FIG. 23, the second semiconductor layer 305 formed of silicon and germanium is formed on a planarized portion of the first semiconductor layer 304 that includes the light receiving portion so that a relatively high relative sensitivity can be obtained near the wavelength of 850 nm (infrared region).

However, in the configuration above, the second semiconductor layer 305 (light receiving portion) is covered by the interlayer insulating film 306, and is not electrically shielded. This configuration is likely to be affected by fixed charges in the interlayer insulating film 306 and a planarization film 308, as well as an electric potential of a pixel electrode 309, which are shown in FIG. 23.

As a result, when there are electrical effects from the surroundings described above on the second semiconductor layer 305 provided in the optical sensor 300a described in Patent Document 2, noise is added to data of received light of the optical sensor 300a, thereby deteriorating the S/N ratio, which is a ratio of the data of received light obtained by the optical sensor 300a with respect to the noise.

The present invention seeks to address the above-mentioned problems. Its object is to provide a photodiode that has a high S/N ratio, which is a ratio of data of received light with respect to noise, and that has high detection accuracy even when sensing by the photodiode is performed using light of an infrared region without increasing the intensity of light of the infrared region that is emitted to an object of detection, a method of manufacturing the photodiode, a display panel substrate having the photodiode, and a display device having the display panel substrate.

### Means for Solving the Problems

In order to solve the problems described above, a photodiode of the present invention is a photodiode that has a first semiconductor layer, a second semiconductor layer, and a third semiconductor layer and that generates different amounts of current depending on an amount of light received on a light receiving surface of the second semiconductor layer. The first semiconductor layer is a semiconductor layer that has a relatively high concentration of an N-type impurity. The second semiconductor layer is either an intrinsic semiconductor layer or a semiconductor layer that has a relatively low impurity concentration. The third semiconductor layer is a semiconductor layer that has a relatively high concentration of a P-type impurity. One of the first semiconductor layer and the third semiconductor layer is formed on the light receiving surface of the second semiconductor layer so as to overlap the light receiving surface of the second semiconductor layer at least partially in a plan view. The other one of the first semiconductor layer and the third semiconductor layer is formed on an opposite surface of the light receiving surface of the second semiconductor layer so as to overlap the light receiving surface and the aforementioned one of the first and third semiconductor layers at least partially in a plan view. In the second semiconductor layer, a relative light receiving sensitivity to respective wavelengths of light has the highest value at a wavelength in an infrared region.

According to the configuration above, in the second semiconductor layer, the relative light receiving sensitivity to the respective wavelengths of light has the highest value at a wavelength in the infrared region. As a result, even if sensing by the photodiode is performed using light of the infrared region without increasing the intensity of light of the infrared region that is emitted to an object of detection, it is possible to achieve a photodiode that has a high S/N ratio, which is a ratio of data of received light with respect to noise, and that has high detection accuracy.

Furthermore, the configuration above has a configuration in which the second semiconductor layer having the light receiving surface is disposed between the first semiconductor layer and the third semiconductor layer at least partially. Because of this, potentials above and under the second semiconductor layer having the light receiving surface can be fixed. As a result, in this configuration, the second semiconductor layer is less likely to be electrically affected by its surroundings.

When the second semiconductor layer is electrically affected by its surroundings, noise is added to data of received light, and the S/N ratio, which is a ratio of data of received light with respect to noise, is deteriorated.

According to the configuration above, it is possible to achieve a photodiode having high detection accuracy.

Furthermore, the configuration above has a configuration in which the first semiconductor layer, the second semiconductor layer, and the third semiconductor layer are laminated at least partially. As a result, the area of the light receiving surface can be larger compared to a PIN photodiode of a lateral configuration and the like.

Furthermore, according to the configuration above, a photodiode can be formed without using a CMOS process.

In order to solve the problems described above, a method of manufacturing the photodiode of the present invention is a method of manufacturing a photodiode that has the following: a first semiconductor layer that is a semiconductor layer having a relatively high concentration of an N-type impurity; a second semiconductor layer that is either an intrinsic semiconductor layer or a semiconductor layer having a relatively low impurity concentration; and a third semiconductor layer that is a semiconductor layer having a relatively high concentration of a P-type impurity, and that generates different amounts of current depending on an amount of received light on a light receiving surface of the second semiconductor layer. In the manufacturing method, one of the first semiconductor layer and the third semiconductor layer is formed. Then, on the one of the first and third semiconductor layers, the second semiconductor layer is formed, and at that time, the second semiconductor layer is formed of a layer in which the relative light receiving sensitivity to the respective wavelengths of light has the highest value at a wavelength in an infrared region. When forming the second semiconductor layer on the aforementioned one of the first and third semiconductor layers, the second semiconductor layer is formed by growing it selectively from a location at which the aforementioned one of the first and third semiconductor layers is formed among a location where such a layer is formed and a location where such a layer is not formed underneath. When forming the other one of the first semiconductor layer and the third semiconductor layer on the second semiconductor layer, the other such layer is formed by growing it selectively from a location at which the second semiconductor layer is formed among a location where the second semiconductor layer is formed and a location where the second semiconductor layer is not formed.

According to the manufacturing method above, the semiconductor layers are laminated by selective growth. Because of this, a resist step using a separate mask is not needed. As a result, the process step can be simplified.

Furthermore, because self-alignment is used, there is no need to obtain a margin between patterns taking into account a pattern shift. As a result, the area of the photodiode can be increased.

Furthermore, because the semiconductor layers are laminated by selective growth, if the first semiconductor layer has crystallinity when the second semiconductor layer is formed on the first semiconductor layer, for example, the second semiconductor layer grows by inheriting the crystallinity of the first semiconductor layer. As a result, the second semiconductor layer becomes either polycrystalline or microcrystalline instead of amorphous, and has higher spectral sensitivity characteristics with respect to a wavelength near 850 nm (infrared region) than an amorphous semiconductor layer.

Furthermore, because the semiconductor layers are laminated by selective growth, in the case of forming the second semiconductor layer on the first semiconductor layer, by performing crystallization of the first semiconductor layer in an oxygen atmosphere so that a certain crystal orientation becomes dominant, for example, the crystal orientation of the second semiconductor layer can be also aligned with that crystal orientation. As a result, it is possible to reduce variations in spectral sensitivity characteristics in the respective photodiode elements.

In order to solve the problems described above, a display panel substrate of the present invention has the above-mentioned photodiode and an active element that are formed on one surface of an insulating substrate.

According to the configuration above, even when sensing by the photodiode is performed using light of an infrared region without increasing the intensity of the light of the infrared region that is emitted to an object of detection, it is possible to achieve a display panel substrate that has a high S/N ratio, which is a ratio of data of received light with respect to noise, and that has high detection accuracy.

In order to solve the problems described above, a display device of the present invention has the above-mentioned display panel substrate and a planar light source device that emits light containing infrared light and visible light in a planar shape.

According to the configuration above, even when sensing by the photodiode is performed using light of an infrared region without increasing the intensity of light of the infrared region that is emitted to an object of detection, it is possible to achieve a display device that has a high S/N ratio, which is a ratio of data of received light with respect to noise, and that has high detection accuracy.

### Effects of the Invention

As described above, the photodiode of the present invention is configured as follows. The first semiconductor layer is a semiconductor layer that has a relatively high concentration of an N-type impurity. The second semiconductor layer is either an intrinsic semiconductor layer or a semiconductor layer that has a relatively low impurity concentration. The third semiconductor layer is a semiconductor layer that has a relatively high concentration of a P-type impurity. One of the first semiconductor layer and the third semiconductor layer is formed on the light receiving surface of the second semiconductor layer so as to overlap the light receiving surface of the second semiconductor layer at least partially in a plan view. The other one of the first semiconductor layer and the third semiconductor layer is formed on an opposite surface of the light receiving surface of the second semiconductor layer so as to overlap the light receiving surface and the one layer at least partially in a plan view. In the second semiconductor layer, the relative light receiving sensitivity to the respective wavelengths of light has the highest value at a wavelength in an infrared region.

As described above, the display panel substrate of the present invention has a configuration in which the above-mentioned photodiode and an active element are formed on one surface of an insulating substrate.

As described above, the display device of the present invention is configured to have the above-mentioned display panel substrate and a planar light source device that emits light containing infrared light and visible light in a planar shape.

As described above, the method of manufacturing the photodiode of the present invention is as follows. Either one layer of the first semiconductor layer or the third semiconductor layer is formed. Then the second semiconductor layer is formed on that layer, and is formed of a layer in which the relative light receiving sensitivity to the respective wavelengths of light has the highest value at a wavelength in an infrared region. When forming the second semiconductor layer on the aforementioned one of the first and third semiconductor layers, the second semiconductor layer is formed by growing it selectively from a locations at which that one of the layers is formed underneath among a location where such a layer is formed and a location where such a layer is not formed. When forming the other one of the first semiconductor layer and the third semiconductor layer on the second semiconductor layer, the other one of the first and third layers is formed by growing it selectively from a location at which the second semiconductor layer is formed among a location where the second semiconductor layer is formed and a location where the second semiconductor layer is not formed.

Therefore, even when sensing by a photodiode is performed using light of an infrared region without increasing the intensity of light of the infrared region that is emitted to an object of detection, it is possible to achieve a photodiode that has a high S/N ratio, which is a ratio of data of received light with respect to noise, and that has high detection accuracy, a method of manufacturing the photodiode, a display panel substrate, and a display device.

### BRIEF DESCRIPTION OF THE DRAWINGS

FIG. 1 is a drawing showing a schematic configuration of a liquid crystal display device according to an embodiment of the present invention.

FIG. 2 is a drawing showing a schematic configuration of a photodiode provided in the liquid crystal display device of an embodiment of the present invention.

FIG. 3 is a drawing showing spectral sensitivity characteristics of an intrinsic semiconductor layer (SiGe) formed of silicon and germanium that is used as a light receiving portion of a photodiode provided in the liquid crystal display device of an embodiment of the present invention.

FIG. 4 is a drawing showing directions in which a current flows in a photodiode. FIG. 4(a) shows a case of a photodiode having a lateral configuration. FIG. 4(b) shows a case of a photodiode provided in a liquid crystal display device according to the present embodiment.

FIG. 5 is a drawing showing a manufacturing process of a liquid crystal display panel provided in a liquid crystal display device according to an embodiment of the present invention.

FIG. 6 is a drawing showing a manufacturing process of a liquid crystal display panel provided in a liquid crystal display device according to an embodiment of the present invention.

FIG. 7 is a drawing showing an example in which a first insulating film is not completely removed so that a first conductive layer is not exposed during a step shown in FIG. 6(a).

FIG. 8 is a drawing for explaining a light receiving area of a light receiving portion in a photodiode having a lateral configuration. FIG. 8(a) shows the light receiving portion seen from above. FIG. 8(b) shows a cross-sectional surface along the line A-A′ in FIG. 8(a).

FIG. 9 is a drawing for explaining a light receiving area of a light receiving portion in a photodiode provided in a liquid crystal display device according to an embodiment of the present invention. FIG. 9(a) shows the light receiving portion viewed from above. FIG. 9(b) shows a cross-sectional surface along the line B-B′ in FIG. 9(a).

FIG. 10 is a drawing for explaining a reason why a film thickness of a light receiving portion of a photodiode and a film thickness of a channel layer of a TFT element provided in a liquid crystal display device according to an embodiment of the present invention can be set flexibly to have the optimum thicknesses for their respective characteristics. FIG. 10(a) shows a schematic configuration of an active matrix substrate provided in the liquid crystal display device of an embodiment of the present invention. FIG. 10(b) shows a schematic configuration of an active matrix substrate that has a photodiode having a lateral configuration.

FIG. 11 is a drawing showing a schematic configuration of a conventional PIN photodiode having a multilayer configuration shown in FIG. 21. FIG. 11(a) shows the conventional PIN photodiode of a multilayer configuration viewed from above. FIG. 11(b) shows a cross-sectional surface along the line A-A′ in FIG. 11(a).

FIG. 12 is a drawing showing a schematic configuration of a photodiode provided in a liquid crystal display device according to an embodiment of the present invention. FIG. 12(a) shows the photodiode provided in the liquid crystal display device of an embodiment of the present invention viewed from above. FIG. 12(b) shows a cross-sectional surface along the line B-B′ in FIG. 12(a).

FIG. 13 shows a manufacturing process of a liquid crystal display device according to another embodiment of the present invention.

FIG. 14 is a magnified view of FIG. 13(b).

FIG. 15 is a drawing for explaining a light receiving area of a light receiving portion in a photodiode provided in a liquid crystal display device according to Embodiment 1. FIG. 15(a) shows the light receiving portion viewed from above. FIG. 15(b) shows a cross-sectional surface along the line A-A′ in FIG. 15(a).

FIG. 16 is a drawing for explaining a light receiving area of a light receiving portion in a photodiode provided in a liquid crystal display device according to another embodiment of the present invention. FIG. 16(a) shows the light receiving portion viewed from above. FIG. 16(b) shows a cross-sectional surface along the line B-B′ in FIG. 16(a).

FIG. 17 is a drawing showing a manufacturing process of a liquid crystal display device according to yet another embodiment of the present invention.

FIG. 18 is a drawing showing a manufacturing process of a liquid crystal display device according to yet another embodiment of the present invention.

FIG. 19 is a drawing showing a display surface of a liquid crystal display device of yet another embodiment of the present invention.

FIG. 20 is a drawing showing spectral sensitivity characteristics of two types of photodiodes provided in a liquid crystal display device of yet another embodiment of the present invention.

FIG. 21 is a schematic cross-sectional view of a conventional image sensor in which a PIN photodiode having a multilayer configuration is used as an optical sensor.

FIG. 22 is a schematic cross-sectional view of a conventional optical sensor that has a PIN photodiode having a lateral configuration.

FIG. 23 is a schematic cross-sectional view of a conventional display device that has a PIN photodiode having a lateral configuration in which two semiconductor layers formed of different materials are laminated.

FIG. 24 is a drawing showing a relative sensitivity (spectral sensitivity characteristics) of amorphous silicon (a-Si) to the respective wavelengths.

FIG. 25 is a drawing showing a relative sensitivity (spectral sensitivity characteristics) of polycrystalline silicon (Poly-Si) to the respective wavelengths.

### DETAILED DESCRIPTION OF EMBODIMENTS

Embodiments of the present invention are described in detail below with reference to the figures. However, dimensions, materials, and shapes of components described in the embodiments, as well as their relative arrangements and the like are merely examples. The scope of the present invention should not be interpreted as being limited by them.

### Embodiment 1

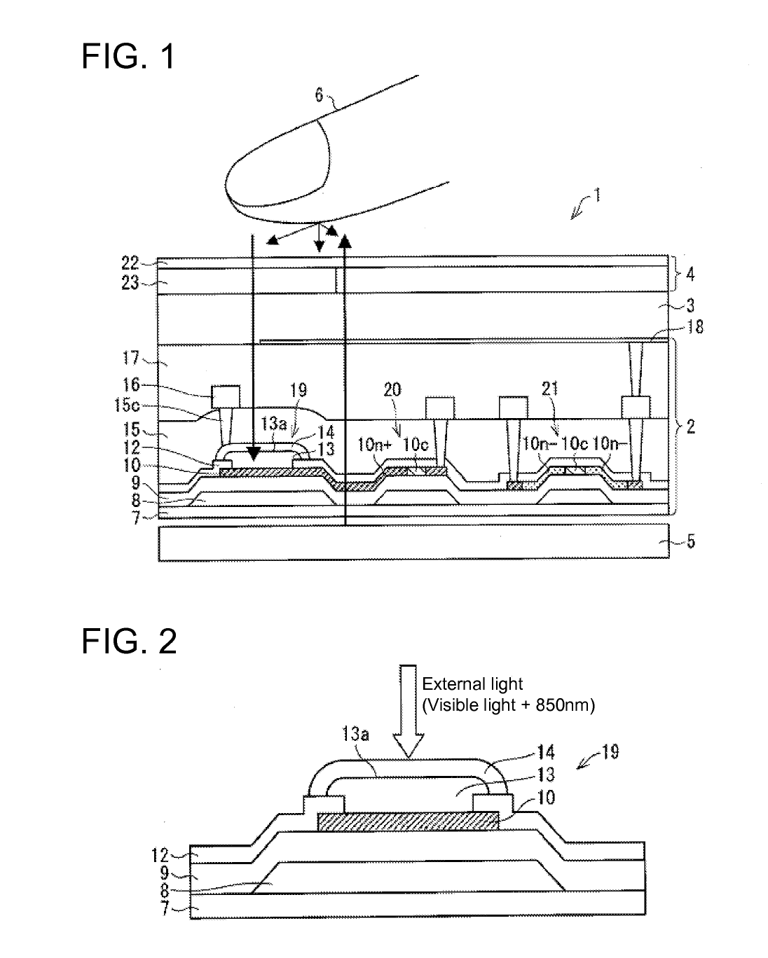

A configuration of a liquid crystal display device 1, which is an example of a display device according to the present invention, is described below with reference to FIGS. 1 and 2.

Here, the display device of the present invention is not limited to the liquid crystal display device 1, and can also be realized as an organic EL display device or the like, for example.

FIG. 1 is a drawing showing a schematic configuration of the liquid crystal display device 1 according to an embodiment of the present invention.

As shown in FIG. 1, the liquid crystal display device 1 is provided with a liquid crystal display panel that is configured to have an active matrix substrate 2 (display panel substrate) and a color filter substrate 4 disposed so as to face the active matrix substrate 2 and that has a configuration in which a liquid crystal layer 3 is encapsulated between these substrates 2 and 4 by a sealing member.

Furthermore, the liquid crystal display device 1 has a planar light source device 5 that emits light containing infrared light and visible light towards the liquid crystal display panel.

Here, on a glass substrate 22 of the color filter substrate 4, a color filter layer 23, a common electrode and an alignment film, which are not shown in the figure, and the like, are provided.

A configuration of the active matrix substrate 2 is described in detail below.

Although not shown in the figure, the active matrix substrate 2 has a display region that is constituted of a plurality of transparent pixel electrodes arranged in a matrix.

In the display region where the respective transparent pixel electrodes are formed, a photodiode 19 that is a sensor for achieving the touch panel function shown in FIG. 1, a TFT element 20 (thin film transistor, active element) that is electrically connected to the photodiode 19, and a pixel TFT element 21 for driving a third conductive layer (transparent pixel electrodes) 18 are provided.

As shown in the figure, light emitted from the planar light source device 5 is reflected by a finger 6 that is an object of detection. The reflected light is detected by the photodiode 19 that is provided at a corresponding location, and the detected signal is imaged. The image is analyzed to detect which location on the liquid crystal display device 1 was touched by the finger 6.

FIG. 2 is a drawing showing a schematic configuration of the photodiode 19 provided in the liquid crystal display device 1 of an embodiment of the present invention.

As shown in the figure, on a glass substrate 7 (insulating substrate) provided in the active matrix substrate 2, a first conductive layer 8 that functions as a light shielding layer in the photodiode 19 and that functions as a gate electrode in the TFT elements 20 and 21 is formed.

A first insulating film 9 is formed so as to cover the first conductive layer 8. On the first insulating film 9, P (phosphorus) is implanted as an N-type impurity to form a first semiconductor layer 10 that is formed of polycrystalline silicon formed in an n+ region.

A third insulating film 12 is formed so as to cover the first insulating film 9 and the first semiconductor layer 10. In the third insulating film 12, an opening is formed so as to expose the first semiconductor layer 10.

A second semiconductor layer 13 that is an intrinsic semiconductor layer (SiGe) formed of silicon and germanium is formed so as to cover (so as to coat) the first semiconductor layer 10 that is exposed from the opening. An upper surface of the second semiconductor layer 13 is a light receiving surface 13a.

Furthermore, B (borane), which is a P-type impurity, is implanted into the second semiconductor layer 13 to form a third semiconductor layer 14 that is formed into a p+ region that covers (so as to coats) the second semiconductor layer 13.

Thus, as shown in FIG. 2, the photodiode 19 has a configuration in which the first semiconductor layer 10, the second semiconductor layer 13, and the third semiconductor layer 14 are laminated in this order. However, the photodiode 19 may have a configuration in which the third semiconductor layer 14, the second semiconductor layer 13, and the first semiconductor layer 10 are laminated in this order.

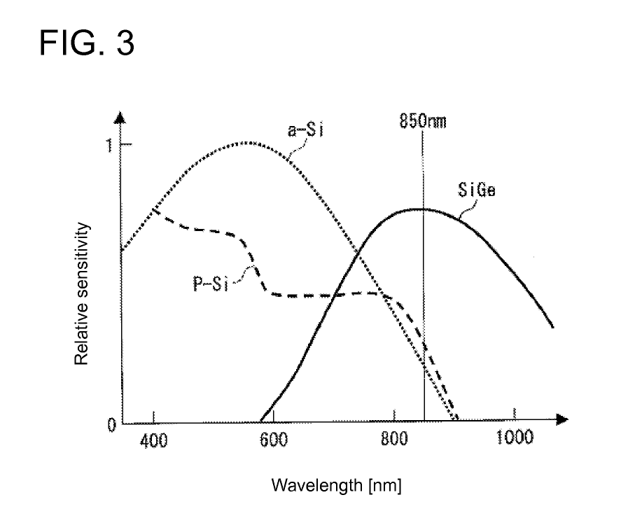

FIG. 3 shows spectral sensitivity characteristics of the intrinsic semiconductor layer (SiGe) formed of silicon and germanium that is used as the light receiving portion of the photodiode 19.

As shown in the figure, the relative sensitivity of polycrystalline silicon (Poly-Si) and amorphous silicon (a-Si) to the respective wavelengths is relatively high in a visible light region, and becomes significantly low near a wavelength of 850 nm (infrared region). However, in the intrinsic semiconductor layer (SiGe) formed of silicon and germanium, which is used as the light receiving portion of the photodiode 19, the relative sensitivity to the respective wavelengths has the highest value near the wavelength of 850 nm (infrared region). In the visible light region, the relative sensitivity is low.

Therefore, it is possible to achieve the photodiode 19 that can increase the sensitivity to only a region near the wavelength of 850 nm (infrared region) and that can suppress the sensitivity to other wavelength regions to be low by using the intrinsic semiconductor layer (SiGe) formed of silicon and germanium as the light receiving portion.

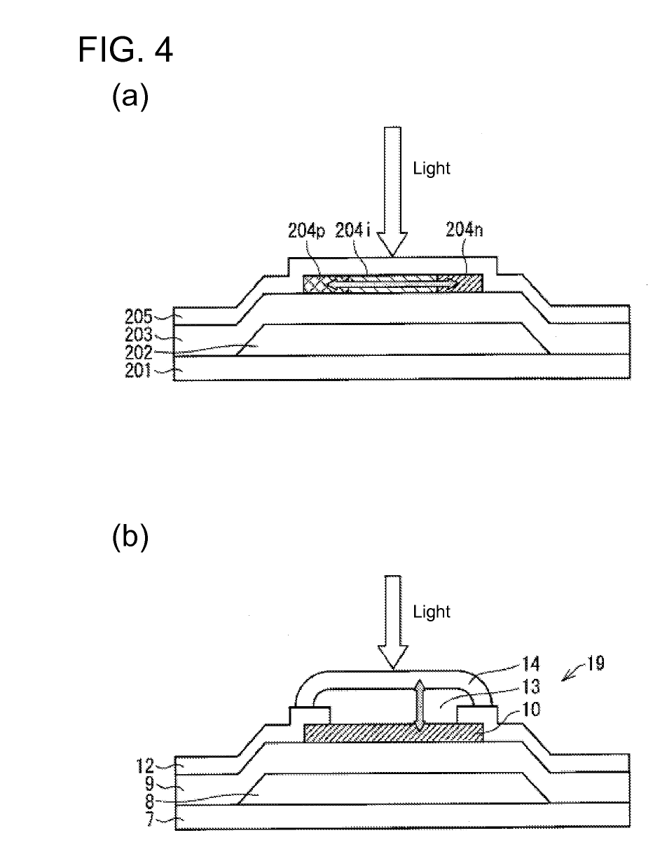

FIG. 4 is a drawing showing differences in directions in which currents flow in a photodiode having a lateral configuration and in the photodiode 19 having a multilayer configuration (vertical configuration) provided in the liquid crystal display device 1 of the present embodiment.

As shown in FIG. 4(a), in the photodiode having a horizontal configuration (lateral configuration) in which a P layer 204p, an I layer (light receiving portion) 204i, and an N layer 204n are arranged in an in-plane direction on the substrate 201, currents flow in left and right directions in the figure.

On the other hand, as shown in FIG. 4(b), in the photodiode having a multilayer configuration (vertical configuration) in which an N layer (first semiconductor layer 10), an I layer (light receiving portion, second semiconductor layer 13), and a P layer (third semiconductor layer 14) are laminated in this order with respect to the substrate 7, currents flow in upward and downward directions in the figure.

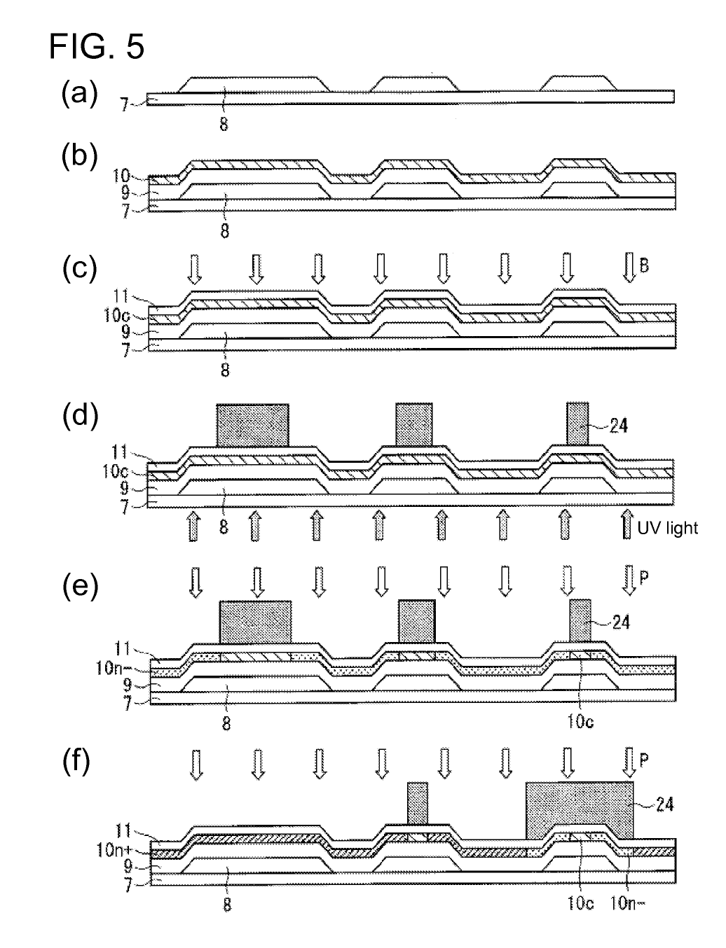

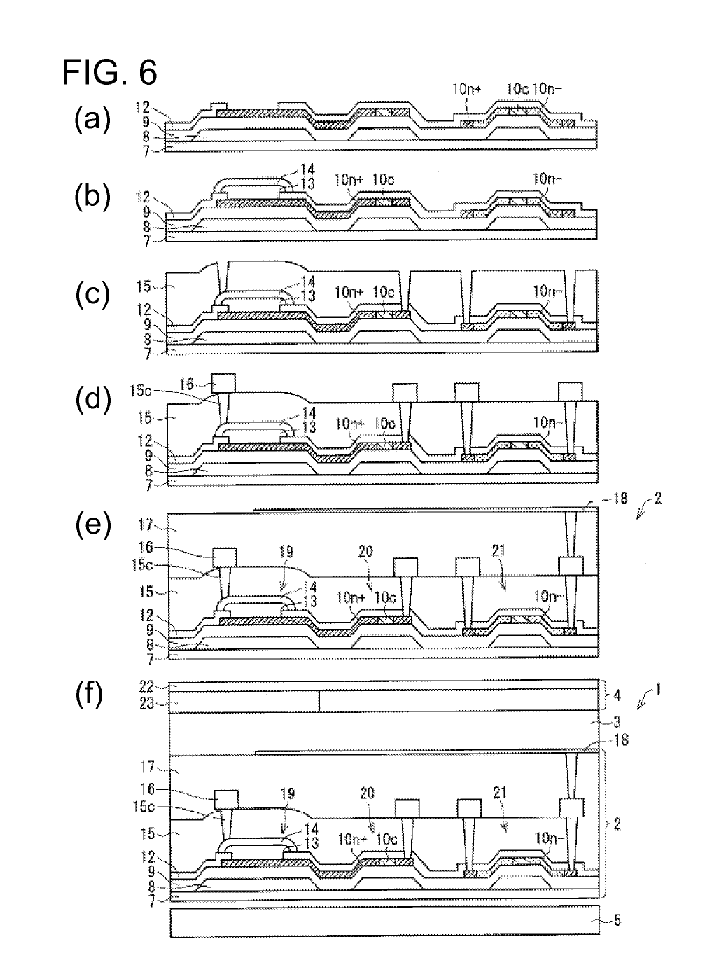

Using FIGS. 5 and 6, a manufacturing process of a liquid crystal display panel provided in the liquid crystal display device 1 of an embodiment of the present invention shown in FIG. 1 is described in detail below.

FIGS. 5 and 6 show a manufacturing process of a liquid crystal display panel provided in the liquid crystal display device 1 of an embodiment of the present invention.

First, as shown in FIG. 5(a), the first conductive layer 8 was formed on the glass substrate 7. The first conductive layer 8 was patterned by etching using a resist that was patterned into a prescribed pattern as a mask.

In the present embodiment, Mo was formed to have a film thickness of 200 nm as the first conductive layer 8. However, it is not limited thereto, and an element selected from Ta, W, Ti, Al, Cu, Cr, Nd, and the like may be used. Alternatively, an alloy material or a compound material that has the above-mentioned elements as a primary material may be used. Alternatively, a multilayer configuration in which they are appropriately combined as necessary may be used.

Next, as shown in FIG. 5(b), the first insulating film 9 and the first semiconductor layer 10 are formed continuously.

In the present embodiment, as the first insulating film 9, silicon oxide was formed to have a film thickness of 300 nm. As the first semiconductor layer 10, amorphous silicon was formed to have a film thickness of 50 nm.

Next, in order to remove hydrogen from the first semiconductor layer 10, annealing was performed at 410 degrees for one hour in a nitrogen atmosphere.

Furthermore, crystallization was performed in order to make the first semiconductor layer 10 polycrystalline.

Here, in order to improve the sensitivity of the photodiode 19, a surface of the first semiconductor layer 10 after the crystallization preferably has many recesses and protrusions. Therefore, in the present embodiment, the crystallization was performed in an oxygen atmosphere in order to form the surface of the first semiconductor layer 10 into recesses and protrusions. Furthermore, by performing the crystallization of the first semiconductor layer 10 in the oxygen atmosphere, the crystal orientation (100) becomes more pronounced.

Here, as the first semiconductor layer 10 before the crystallization, amorphous silicon was used. However, amorphous germanium, amorphous silicon germanium, amorphous silicon carbide, or the like may be used.

Next, as shown in FIG. 5(c), a second insulating film 11 was formed.

In the present embodiment, silicon oxide was formed to have a film thickness of 80 nm.

Then, a first impurity was implanted in order to control the Vth of the TFT element 20 and the pixel TFT element 21.

In the present embodiment, B (boron) was implanted to 2.5 E13/cm² at 60 keV as the first impurity to form a channel region 10c in the first semiconductor layer 10 such that a current (current per unit width of the TFT element) became 1 E-10 A/μm or less when a voltage of 0V was applied to the gate electrodes of the TFT elements 20 and 21.

Here, the above-mentioned “1 E-10” means 1×10⁻¹⁰. The above-mentioned “2.5 E13” means 2.5×10¹³.

Next, as shown in FIG. 5(d), a positive type resist 24 was applied. An exposure of the resist 24 was performed from a back surface side of the glass substrate 7 using the first conductive layer 8 as a mask to form a resist pattern that was slightly smaller than the first conductive layer 8.

Next, as shown in FIG. 5(e), using the resist 24 as a mask, a second impurity was implanted to form an n− region 10n− of the first semiconductor layer 10. At the same time, in a region under the resist 24, the channel region 10c was formed.

In the present embodiment, P (phosphorus) was implanted to 3 E13/cm² at 55 keV as the impurity such that the sheet resistance of the n− region became 10 k to 200 kΩ/□. Then, the resist 24 was removed.

Then, as shown in FIG. 5(f), the resist 24 is applied and patterned again in order to form an n+ region 10n+ in the first semiconductor layer 10 in the formation region of the photodiode 19 and the TFT elements 20 and 21.

Using the patterned resist 24 as a mask, a third impurity is implanted into the first semiconductor layer 10 to form the n+ region 10n+. At the same time, in the region under the resist 24, the channel region 10c and the n− region 10n− are formed.

In the present embodiment, P (phosphorus) was implanted to 5 E15/cm² at 45 keV as the third impurity such that the sheet resistance of the n+ region 10n+ became 200 to 10 kΩ/□.

Then, the resist 24 and the second insulating film 11 are removed. Next, the first semiconductor layer 10 is patterned.

Next, as shown in FIG. 6(a), the third insulating film 12 is formed.

In the present embodiment, silicon oxide was formed to have a film thickness of 100 nm as the third insulating film 12.

Then, in a region where the photodiode 19 is to be formed, a resist (not shown in the figure) is patterned. Using the resist as a mask, the third insulating film 12 is removed by etching to expose the n+ region 10n+ of the first semiconductor layer 10.

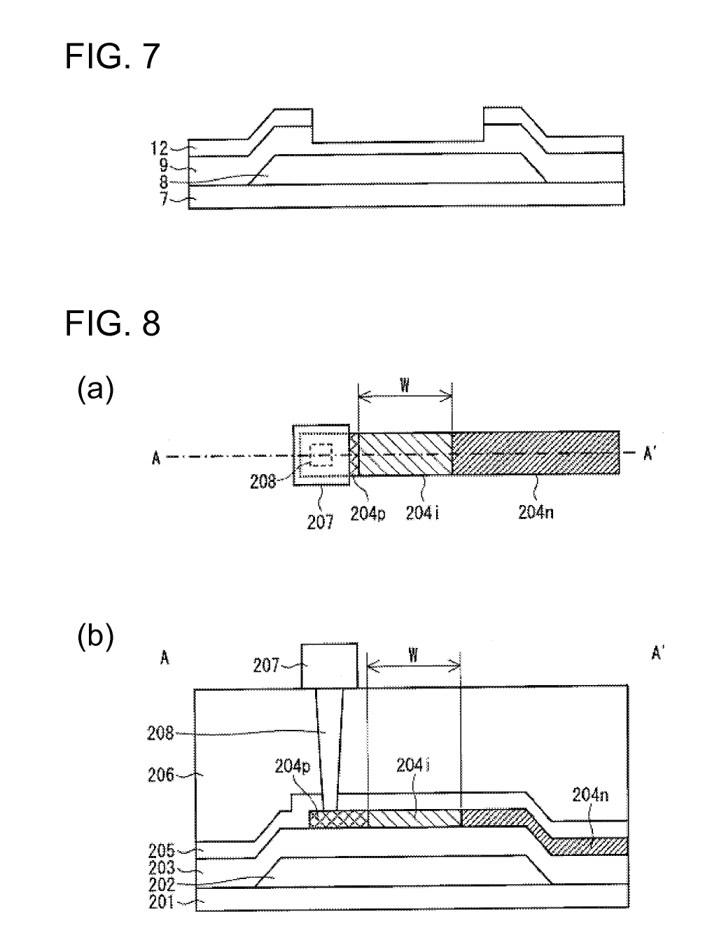

Here, as shown in FIG. 7, at a portion above the first conductor layer 8 where the n+ region 10n+ is not formed, the first insulating film 9 and the third insulating film 12 preferably are removed at the same time for contact formation in a later step. However, the first insulating film 9 preferably is not removed completely so that the first conductive layer 8 is not exposed. Here, in FIG. 7, the n+ region 10n+ is not shown in the figure.

Further, if a contact is formed on the first conductive layer 8 of the photodiode 19 in a later step, the third insulating film 12 is removed. However, if the contact is not formed in the later step, the third insulating film 12 is not removed.

Next, as shown in FIG. 6(b), the second semiconductor layer 13 and the third semiconductor layer 14 are grown only in a region in which the first semiconductor layer 10 is exposed.

In the present embodiment, selective growth is performed using Si₂H₆ and GeH₄ at a substrate temperature of 550° C. so as to form an intrinsic SiGe layer of Si_{0.8}Ge_{0.2} having a film thickness of 200 nm as the second semiconductor layer 13. Furthermore, selective growth is performed using Si₂H₆, GeH₄, and B₂H₆ at a substrate temperature of 550° C. so as to form a p+ SiGe layer of Si_{0.8}Ge_{0.2} having a film thickness of 50 nm as the third semiconductor layer 14.

Here, in a step of heating the substrate in order to form the second semiconductor layer 13 and the third semiconductor layer 14, the first, second, and third impurities inside the channel region 10c, the n− region 10n−, and the n+ region 10n+ of the first semiconductor layer 10 are activated at the same time.

The present invention is not limited thereto. As the second semiconductor layer 13, a multilayer configuration of a SiGe layer of Si_{0.8}Ge_{0.2} of the n+ type having a film thickness of 50 nm, which is formed by selective growth at a substrate temperature of 550° C. using Si₂H₆, GeH₄, and PH₃, and an intrinsic SiGe layer of Si_{0.8}Ge_{0.2} having a film thickness of 50 to 200 nm, which is formed by selective growth at a substrate temperature of 550° C. using Si₂H₆ and GeH₄.

Here, during the selective growth, the second semiconductor layer 13 and the third semiconductor layer 14 are not formed on the silicon oxide. Furthermore, as shown in FIG. 7, even when the third insulating film 12 above the first conductive layer 8 is removed, the silicon oxide of the first insulating film 9 covers the first conductive layer 8. Because of this, the second semiconductor layer and the third semiconductor layer are not formed.

In the present embodiment, a polycrystalline silicon layer (Poly-Si) of the n+ type is used as the first semiconductor layer 10, and a SiGe layer of the p+ type is used as the third semiconductor layer 14, respectively. However, a polycrystalline silicon layer (Poly-Si) of the p+ type may be used as the first semiconductor layer 10, and a SiGe layer of the n+ type may be used as the third semiconductor layer 14 instead.

Next, as shown in FIG. 6(c), a fourth insulating film 15 was formed.

In the present embodiment, as the fourth insulating film 15, a multilayer configuration of silicon nitride formed to have a film thickness of 250 nm and silicon oxide formed to have a film thickness of 550 nm was used.

Then, a resist was formed, and patterning and etching were performed to form contact holes on a selected first semiconductor layer, on a selected third semiconductor layer 14, and on a selected first conductive layer 8 that is not shown in the figure.

Furthermore, as shown in FIG. 6(d), a second conductive layer 16 was formed. Then, a resist was formed, and patterning and etching were performed.

In the present embodiment, a conductive layer in which, a Ti layer (film thickness of 100 nm), an Al layer (film thickness of 500 nm), and a Ti layer (film thickness of 100 nm) in that order from an upper layer were laminated as the second conductive layer 16. However, the present invention is not limited thereto.

Then, for hydrogenation and for recovery from process damage, annealing was performed in an H₂ atmosphere for one hour at 300 to 400 degrees.

Next, as shown in FIG. 6(e), a fifth insulating film 17 was formed, and a contact hole was formed.

In the present embodiment, a photosensitive resin was used as the fifth insulating film 17, and patterning was performed to form the contact hole. Here, the film thickness of the fifth insulating film 17 was set at 1 to 4 μm.

Then, after a third conductive layer 18 was formed, a resist was patterned into a prescribed pattern. Then, etching was performed using the resist as a mask to form the third conductive layer 18 that becomes a pixel electrode.

In the present embodiment, ITO (Indium Tin Oxide) was formed to have a film thickness of 100 nm as the third conductive layer 18. However, IZO (Indium Zinc Oxide) or the like may be used.

Next, as shown in FIG. 6(f), the active matrix substrate 2 in which the photodiode 19 and the TFT elements 20 and 21 were formed and the color filter substrate 4 in which the color filter layer 23 was disposed to face the active matrix substrate 2 were attached to each other. The liquid crystal layer 3 was injected therebetween to manufacture the liquid crystal display device 1 having the photodiode 19.

Here, at a location on the color filter substrate 4 that faces the photodiode 19, a structure that transmits light near a wavelength of 850 nm (infrared region) can be used.

In the present embodiment, a separate transparent layer was provided in the color filter layer 23. However, there is no need to provide the transparent layer separately if the color filter layer 23 transmits light near a wavelength of 850 nm (infrared region), and such a color filter layer 23 can be used directly.

In FIGS. 5 and 6, composition elements of the respective conductive films, the respective insulating films, the respective semiconductor layers, and the respective impurities (materials, film thicknesses, implantation amount, a single layer or a multilayer, and the like) may be appropriately changed so that the liquid crystal display device 1 having the built-in photodiode 19 can achieve desired performance.

Furthermore, in the present embodiment, N-channel TFTs were formed as the TFT elements 20 and 21. Alternatively, P-channel TFTs may be formed. However, when the P-channel TFTs are formed, the third semiconductor layer 14 needs to be changed to a SiGe layer showing n+.

Furthermore, when using a multilayer configuration as the second semiconductor layer 13, a multilayer configuration of a SiGe layer of the p+ type and an intrinsic SiGe layer needs to be used.

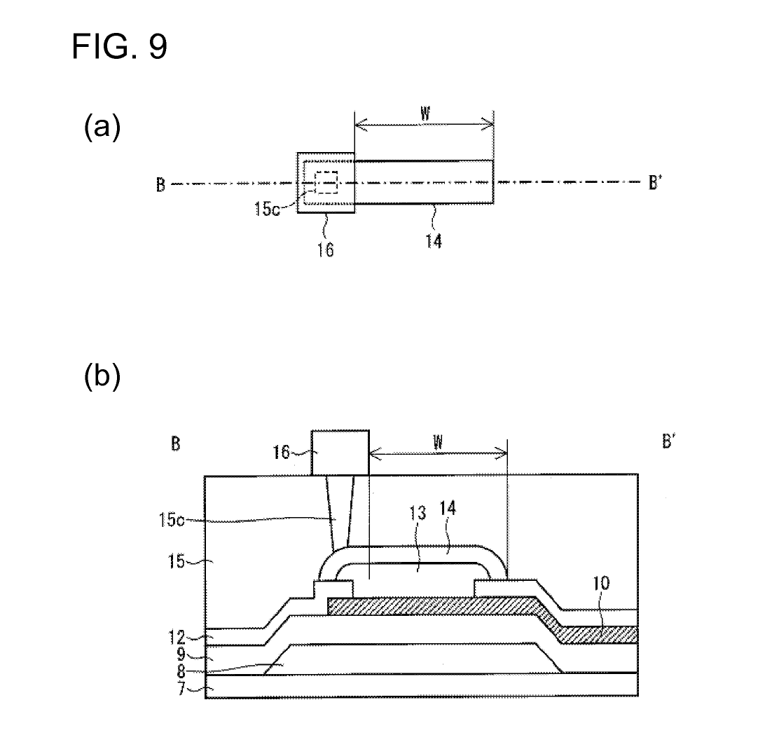

A difference in light receiving areas of light receiving portions between a photodiode having a lateral configuration and the photodiode 19 having a multilayer configuration (vertical configuration) provided in the liquid crystal display device 1 of the present embodiment is described below with reference to FIGS. 8 and 9.

FIG. 8(a) shows a plan view of the photodiode having a lateral configuration. FIG. 8(b) shows a cross-sectional view taken along A-A′ of FIG. 8(a).

As shown in FIG. 8(a) and FIG. 8(b), the photodiode of a lateral configuration is formed such that an I layer (light receiving portion) 204i is disposed between a P layer 204p and an N layer 204n on a single planar surface.

Therefore, regions in which the P layer 204p and the N layer 204n are formed need to be secured on the single planar surface. Because of this, a width in the lengthwise direction of the I layer (light receiving portion) 204i, i.e., a width W in the lengthwise direction of the light receiving portion, cannot be increased unless the size of the photodiode is increased.

Even though a conductive layer 207 is electrically connected to the P layer 204p through a contact hole 208 formed in a second insulating layer 205 and a third insulating layer 206, the conductive layer 207 and the I layer (light receiving portion) 204i are provided so as not to overlap each other in a plan view. As a result, the light receiving area of the light receiving portion is not reduced by forming the conductive layer 207.

On the other hand, FIG. 9(a) shows a plan view of the photodiode 19 of a multilayer configuration (vertical configuration) provided in the liquid crystal display device 1 of the present embodiment. FIG. 9(b) shows a cross-sectional view along B-B′ of FIG. 9(a).

As shown in FIG. 9(b), in the photodiode 19, an N layer (first semiconductor layer 10), an I layer (light receiving portion, second semiconductor layer 13), and a P layer (third semiconductor layer 14) are laminated in this order in a vertical direction instead of on a single planar surface.

Therefore, unlike the photodiode of the lateral configuration described above, there is no need to secure regions to form the P layer 204p and the N layer 204n on a single planar surface in the photodiode 19. Because of this, the I layer (light receiving portion, second semiconductor layer 13) can be formed larger.

As shown in FIG. 9(b), the second conductive layer 16 is electrically connected to the P layer (third semiconductor layer 14) through a contact hole 15c formed in the fourth insulating film 15. As shown in FIG. 9(a) and FIG. 9(b), the second conductive layer 16 and the I layer (light receiving portion, second semiconductor layer 13) are formed to partially overlap each other in a plan view.

Therefore, in the photodiode 19, the second conductive layer 16 and the I layer (light receiving portion, second semiconductor layer 13) overlap each other in a plan view. Because of this, the light receiving area of the light receiving portion is substantially decreased.

However, an increased amount (compared to the I layer (light receiving portion) 204i provided in the photodiode of the lateral configuration) of the I layer (light receiving portion, second semiconductor layer 13) is larger than the decreased amount described above. As a result, the light receiving area of the light receiving portion in the photodiode 19 can be made larger than the light receiving area of the light receiving portion in the photodiode of the lateral configuration.

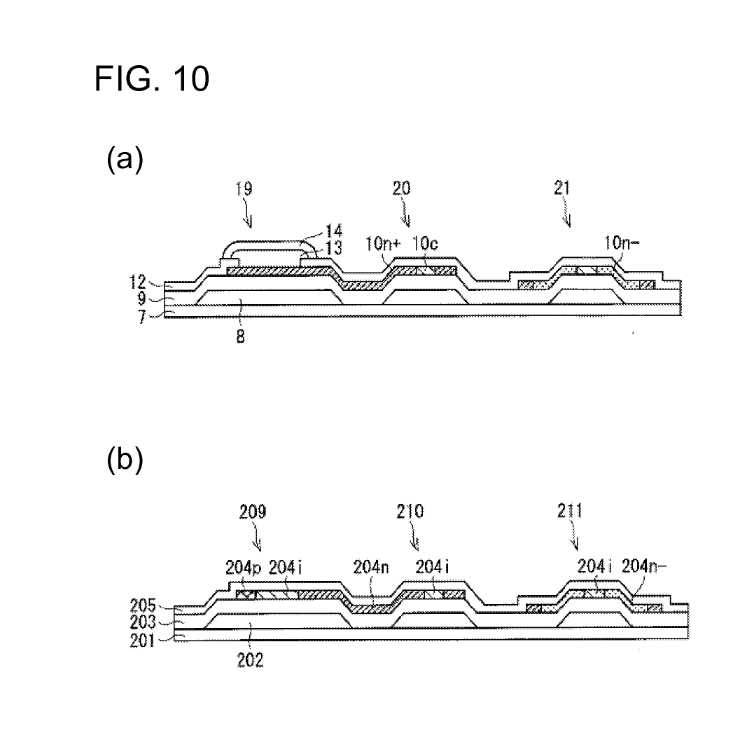

A reason why the film thickness of the light receiving portion of the photodiode 19 provided in the liquid crystal display device 1 of an embodiment of the present invention and the film thicknesses of channel layers of the TFT elements 20 and 21 can be set flexibly to have optimum thicknesses for their respective characteristics is described below with reference to FIG. 10.

FIG. 10(a) shows a schematic configuration of the active matrix substrate 2 having the photodiode 19 and the TFT elements 20 and 21. FIG. 10(b) shows a schematic configuration of an active matrix substrate having a photodiode 209 of a lateral configuration and TFT elements 210 and 211.

As shown in FIG. 10(a), the light receiving portion in the photodiode 19 is formed of the second semiconductor layer 13, and the channel layers in the TFT elements 20 and 21 are formed of the first semiconductor layer 10. Thus, the light receiving portion of the photodiode 19 and the channel layers of the TFT elements 20 and 21 are formed of different layers.

Therefore, the film thickness of the light receiving portion of the photodiode 19 and the film thicknesses of the channel layers of the TFT elements 20 and 21 can be separately set to have the optimum thicknesses for their respective characteristics.

On the other hand, in the configuration shown in FIG. 10(b), a light receiving portion 204i of the photodiode 209 and the channel layers 204i of the TFT elements 210 and 211 are formed of the same semiconductor layer.

Thus, the film thickness of the light receiving portion 204i of the photodiode 209 and the film thicknesses of the channel layers 204i of the TFT elements 210 and 211 are formed to have the same film thicknesses. As a result, they cannot be formed to have different film thicknesses, respectively, unless a separate etching step is added.

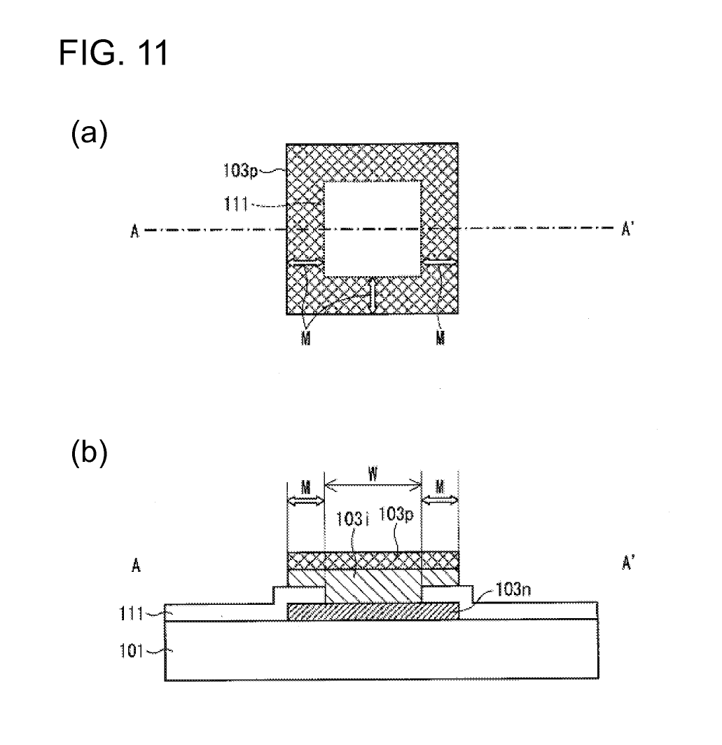

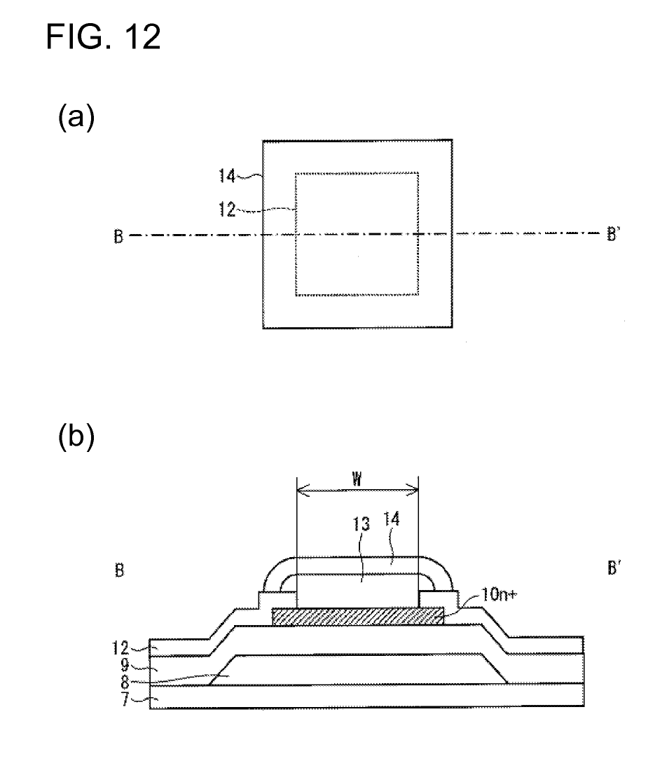

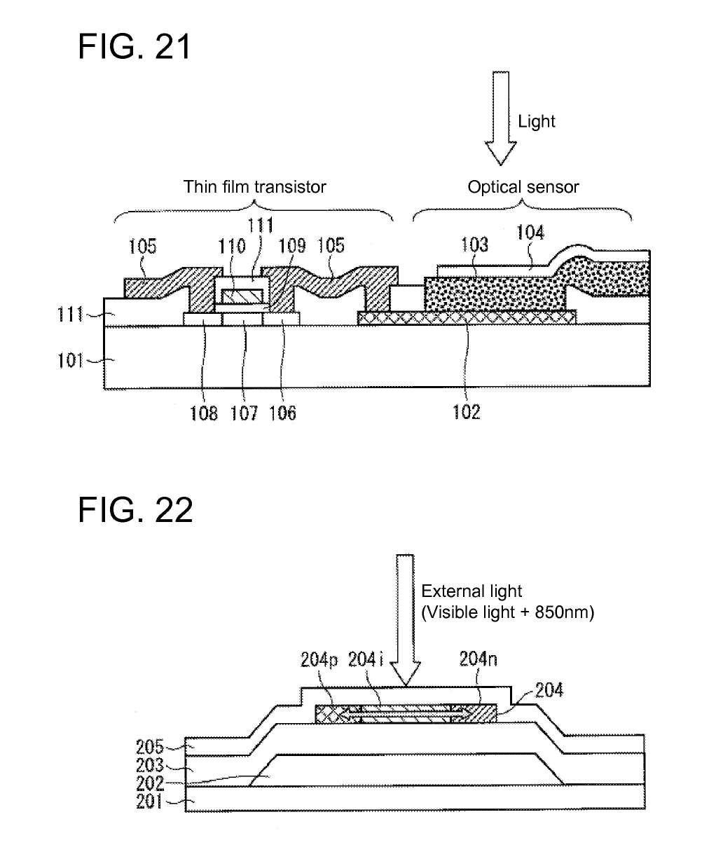

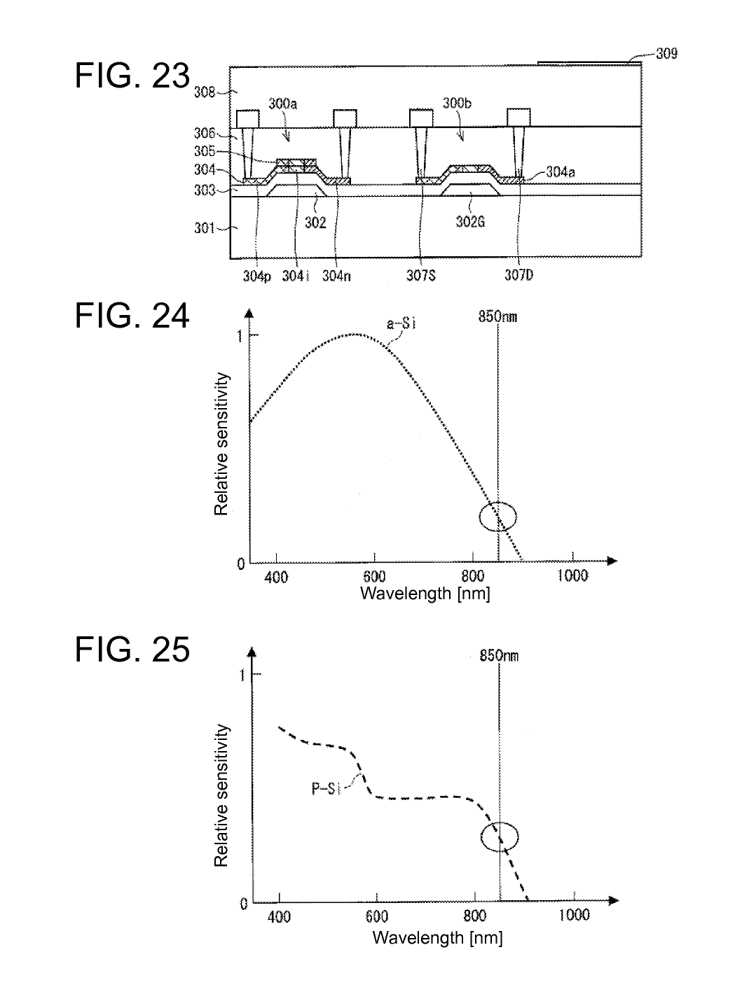

A reason why the light receiving portion of the photodiode 19 provided in the liquid crystal display device 1 of an embodiment of the present invention can be formed larger than a light receiving portion of a conventional PIN photodiode having a multilayer configuration shown in FIG. 21 is described below with reference to FIGS. 11 and 12.

FIG. 11 shows a schematic configuration of the conventional PIN photodiode of the multilayer configuration shown in FIG. 21.

FIG. 11(a) shows a plan view of the conventional PIN photodiode of the multilayer configuration. FIG. 11(b) shows a cross-sectional view along A-A′ of FIG. 11(a).

As shown in FIG. 11(a) and FIG. 11(b), in order to form the photodiode, after a step of patterning an N-type amorphous silicon carbide layer 103n, a step of patterning the interlayer insulating film 111 and a step of patterning a P-type amorphous silicon carbide layer 103p and an intrinsic amorphous silicon layer 103i are needed.

Thus, after the step of patterning the N-type amorphous silicon carbide layer 103n, two patterning steps are needed. Taking into account a pattern shift and the like in the respective patterning steps, margins M are needed between the patterns formed in the respective patterning steps. As a result, the light receiving portion of the conventional PIN photodiode of the multilayer configuration becomes narrower by the amount of the margins M.

FIG. 12 shows a schematic configuration of the photodiode 19 provided in the liquid crystal display device 1 of an embodiment of the present invention.

FIG. 12(a) shows a plan view of the photodiode 19. FIG. 12(b) shows a cross-sectional view along B-B′ of FIG. 12(a).

As shown in FIG. 12(a) and FIG. 12(b), in order to form the photodiode 19, after a step of patterning the first semiconductor layer 10 (n+ region 10n+), only one step of patterning the third insulating film 12 is needed instead of two patterning steps.

This is because, as described above in the description of the manufacturing process of the liquid crystal display panel, in the photodiode 19, the second semiconductor layer 13 formed on the first semiconductor layer 10 (n+ region 10n+) and the third semiconductor layer 14 formed on the second semiconductor layer 13 are laminated by selective growth, which does not require a patterning step.

Therefore, only the step of patterning the third insulating film 12 is needed. Because of this, unlike the conventional PIN photodiode of the vertical configuration, the margins M are not needed. As a result, the light receiving portion of the photodiode 19 can be formed larger.

### Embodiment 2

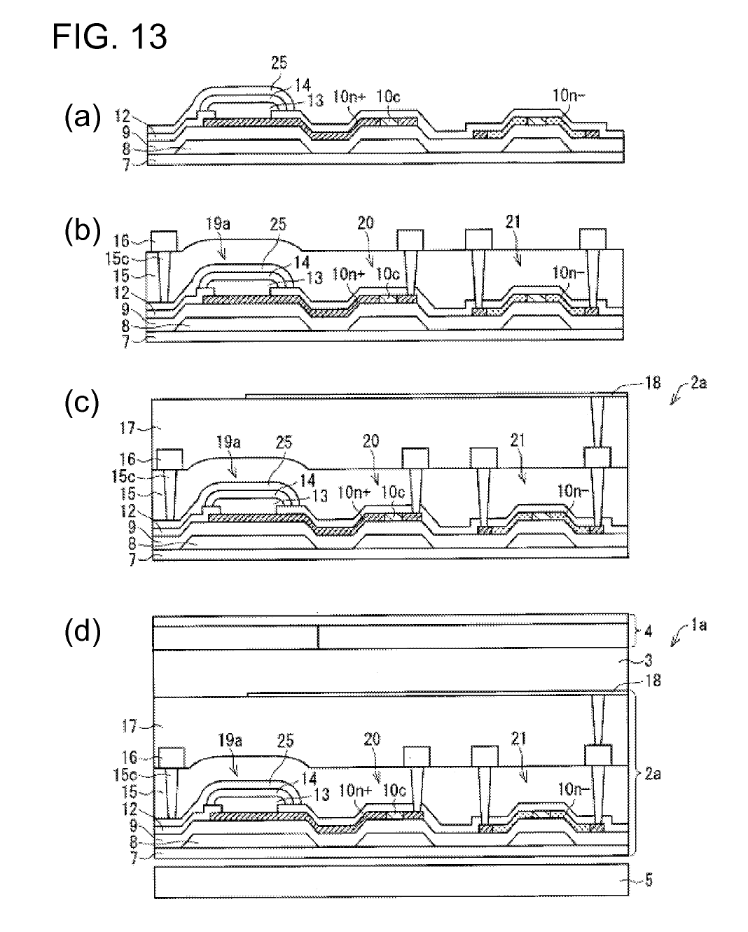

Next, Embodiment 2 of the present invention is described with reference to FIGS. 13 to 15. The present embodiment is different from Embodiment 1 in that a transparent conductive layer 25 is formed in addition so as to cover the third semiconductor layer 14; that the transparent conductive layer 25 has a portion that does not cover the second semiconductor layer 13 in a plan view; and that the transparent conductive layer 25 is electrically connected to an external wiring line at the non-covering portion. The other configurations are as described in Embodiment 1. In order to facilitate description, members having the same functions as the members shown in drawings of Embodiment 1 are given the same reference characters, and their description is omitted.

FIG. 13 shows a manufacturing process of a liquid crystal display device 1a according to an embodiment of the present invention.

After the steps from FIG. 5(a) to FIG. 5(f) and the steps from FIG. 6(a) to FIG. 6(b) were performed, the transparent conductive layer 25 was formed on an overall surface so as to cover the third semiconductor layer 14. Then, a resist was patterned into a prescribed pattern on the transparent conductive layer 25. Using the resist as a mask, the transparent conductive layer 25 was etched to pattern the transparent conductive layer 25 into a shape shown in FIG. 13(a).

In the present embodiment, ITO was formed to have a film thickness of 100 nm as the transparent conductive layer 25. However, the present invention is not limited thereto, and IZO or the like may be used.

Next, using the same step as FIG. 6(c), the fourth insulating film 15 was formed. Then, as shown in FIG. 13(b), contact holes were formed on the formation region of the photodiode 19a and on the formation regions of the TFT elements 20 and 21.

Then, using the same step as FIG. 6(d), the second conductive layer 16 was formed. Then, a resist was formed, and patterning and etching were performed to electrically connect the second conductive layer 16 to the transparent conductive layer 25 in the photodiode 19a through the contact hole 15c.

Here, as shown in FIG. 13(b), the transparent conductive layer 25 has a portion that does not cover the second semiconductor layer 13 in a plan view. In this non-covering portion, the second conductive layer 16 connected to an external wiring line was electrically connected to the transparent conductive layer 25 of the photodiode 19a through the contact hole 15c.

Next, using the same step as FIG. 6(e), an active matrix substrate 2a shown in FIG. 13(c) was manufactured.

Finally, using the same step as FIG. 6(f), the liquid crystal display device 1a shown in FIG. 13(d) was manufactured.

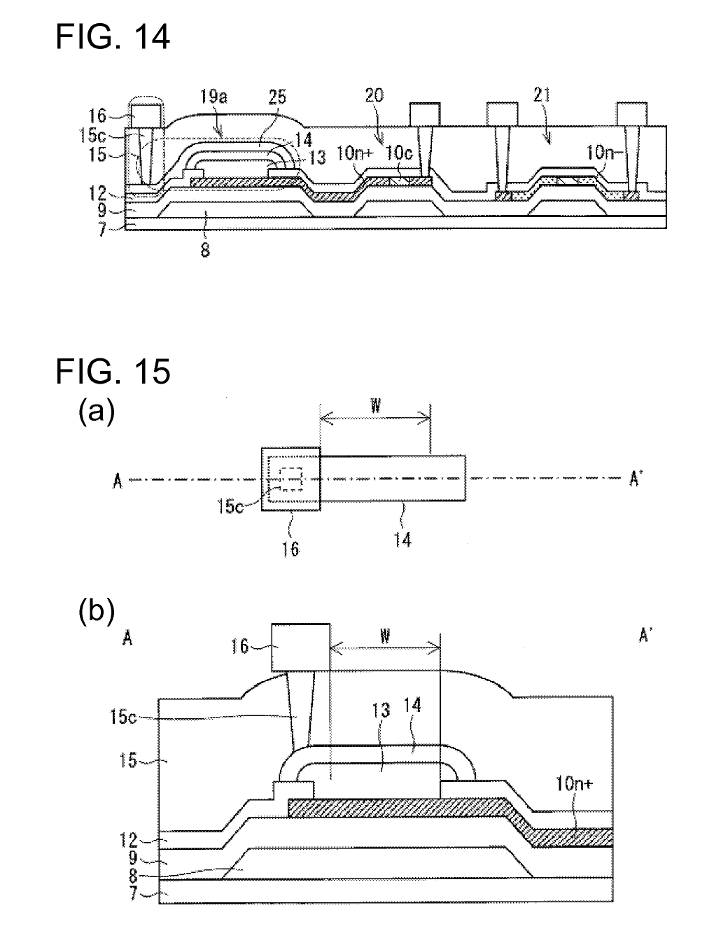

FIG. 14 is a magnified view of FIG. 13(b).

As shown in the figure, the transparent conductive layer 25 of the photodiode 19a and the second conductive layer 16 connected to the external wiring line are electrically connected to each other outside the formation region of the photodiode 19a, i.e., outside the formation region of the second semiconductor layer 13.

In Embodiment 1 described above, the third semiconductor layer 14 formed on a light receiving surface 13a of the second semiconductor layer 13 is used as an electrode for reading out a signal of the photodiode 19. In order to increase the amount of light entering the light receiving surface 13a of the second semiconductor layer 13, the third semiconductor layer 14 preferably is formed thin.

However, when the third semiconductor layer 14 is formed thin, the sheet resistance becomes higher (approximately several k to MΩ/□), and it becomes more difficult to read out the signal of the photodiode 19.

According to the configuration of the present embodiment, the transparent conductive layer 25 formed so as to cover the third semiconductor layer 14 formed on the light receiving surface 13a of the second semiconductor layer 13 can be used as the electrode for reading out the signal of the photodiode 19a. Because of this, the sheet resistance can be reduced to approximately 1 to several hundred Ω/□, and it becomes easier to read out the signal. Furthermore, taking this into an account, the third semiconductor layer 14 can be formed thin. As a result, the amount of light entering the light receiving surface 13a of the second semiconductor layer 13 can be increased.

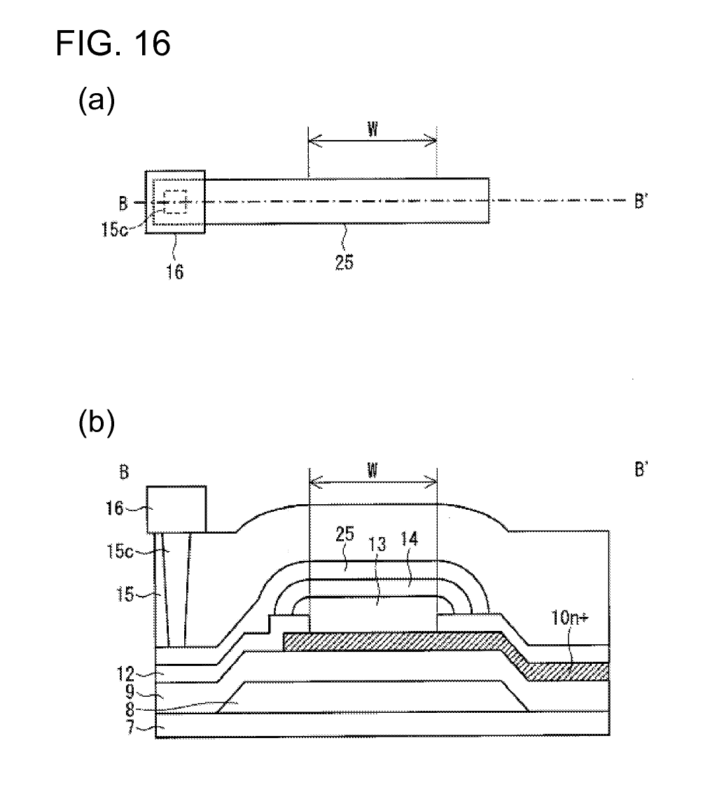

A difference in light receiving areas of the light receiving portions between the photodiode 19 provided in the liquid crystal display device 1 of Embodiment 1 and the photodiode 19a provided in the liquid crystal display device 1a of the present embodiment is described below with reference to FIGS. 15 and 16.

FIG. 15(a) shows a plan view of the photodiode 19. FIG. 15(b) shows a cross-sectional view along A-A′ of FIG. 15(a).

Further, FIG. 16(a) shows a plan view of the photodiode 19a. FIG. 16(b) shows a cross-sectional view along B-B′ of FIG. 16(a).

As shown in FIG. 15(a) and FIG. 15(b), in the photodiode 19, the third semiconductor layer 14 used as the electrode for reading out a signal and the second conductive layer 16 connected to the external wiring line are electrically connected to each other through the contact hole formed on the second semiconductor layer 13. Because of this, the light receiving area of the light receiving portion of the photodiode 19 is reduced by the formation of the second conductive layer 16.

On the other hand, in the photodiode 19a according to the present embodiment shown in FIG. 16(a) and FIG. 16(b), the transparent conductive layer 25 used as the electrode for reading out a signal and the second conductive layer 16 connected to the external wiring line are electrically connected to each other through the contact hole that is formed outside the formation region of the second semiconductor layer 13 instead of the contact hole formed on the second semiconductor layer 13. Because of this, it is possible to secure the light receiving area of the light receiving portion of the photodiode 19a to be larger than the light receiving area of the light receiving portion of the photodiode 19.

Thus, in the configuration above, the transparent conductive layer 25 has a portion that does not cover the second semiconductor layer 13 in a plan view. In the non-covering portion, the transparent conductive layer 25 is electrically connected to the external wiring line. As a result, the amount of light entering the light receiving surface 13a of the second semiconductor layer 13 can be increased.

Furthermore, as shown in FIG. 13(c), when the third conductive layer (transparent pixel electrode) 18 or the like is formed above the transparent conductive layer 25 through the transparent insulating layers 15 and 17, a transparent auxiliary capacitance can be formed. As a result, the aperture ratio can be increased in the liquid crystal display device 1a.

### Embodiment 3

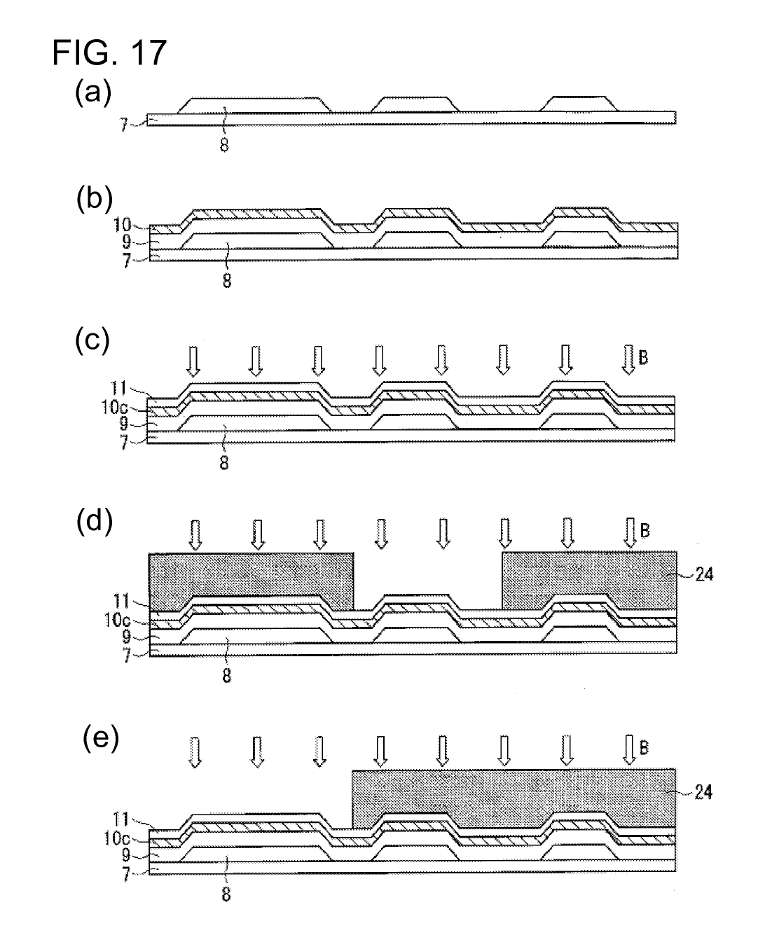

Next, Embodiment 3 of the present invention is described with reference to FIGS. 17 to 20. The present embodiment is different from Embodiment 1 in that a second photodiode 26 having a light receiving portion that has the highest value at a wavelength in a visible light region and a P-channel TFT element 27 are further provided in addition to the photodiode 19 having the light receiving portion formed of silicon and germanium and the N-channel TFT elements 20 and 21, which are shown in Embodiment 1. Other configurations are as described in Embodiment 1. In order to facilitate description, members having the same functions as the members shown in the figures of Embodiment 1 are given the same reference characters, and their description is omitted.

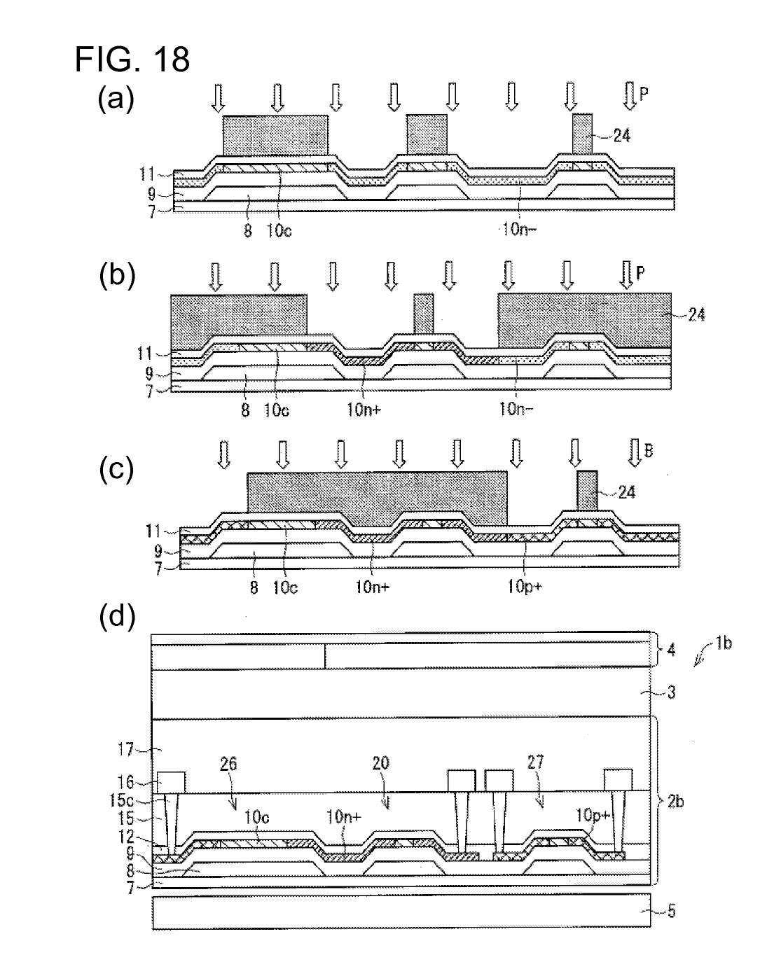

A manufacturing process of a liquid crystal display device 1b according to the present embodiment is described below in detail with reference to FIGS. 17 and 18.

FIGS. 17 and 18 show a manufacturing process of the liquid crystal display device 1b according to an embodiment of the present invention.

First, as shown in FIG. 17(a), the first conductive layer 8 is formed on the glass substrate 7. Using a resist that is patterned into a prescribed pattern as a mask, etching was performed to pattern the first conductive layer 8.

Next, as shown in FIG. 17(b), the first insulating film 9 and the first semiconductor layer 10 are continuously formed.

Here, steps of FIGS. 17(a) and 17(b) are the same as the steps of FIGS. 5(a) and 5(b), and detailed description is omitted.

Next, as shown in FIG. 17(c), the second insulating film 11 is formed.

In the present embodiment, silicon oxide was formed to have a film thickness of 80 nm as the second insulating film 11. Then, a first impurity was implanted under the following conditions for controlling the Vth of the P-channel TFT element 27.

As the first impurity, B (boron) was implanted to 1.5 E13/cm² at 60 keV such that a current (current per unit width of the TFT) became 1 E-11 A/μm or less when a voltage of 0V was applied to a gate electrode of the P-channel TFT element 27.

Next, as shown in FIG. 17(d), the resist 24 was patterned so as to cover regions where the second photodiode 26 and the P-channel TFT element 27 were to be formed.

Then, a fourth impurity was implanted for controlling the Vth of the N-channel TFT element 20.

In the present embodiment, B (boron) was implanted to 1 E13/cm² at 60 keV as the fourth impurity such that a current (current per unit width of the TFT) became 1 E-10 A/μm or less when a voltage of 0V was applied to a gate electrode of the N-channel TFT element 20. Then, the resist 24 was removed.

Next, as shown in FIG. 17(e), the resist 24 was patterned again so as to cover a portion excluding the formation region of the second photodiode 26. A fifth impurity was implanted for adjusting the impurity concentration in the light receiving portion of the PIN diode of the lateral configuration.

In the present embodiment, B (boron) was implanted to 5 E12/cm² at 60 keV as the fifth impurity so that the light receiving sensitivity of the second photodiode 26 to visible light became the highest. Then, the resist 24 was removed.

Here, in the present embodiment, a PIN photodiode having a lateral configuration was used as the second photodiode 26. However, the present invention is not limited thereto as long as the light receiving sensitivity is at the maximum to visible light, and therefore, a photodiode having a multilayer configuration (vertical configuration) may be used.

Next, as shown in FIG. 18(a), the resist 24 is applied again. Using the first conductive layer 8 as a mask, the resist 24 undergoes an exposure from the back surface side of the glass substrate 7 to form a resist pattern that is slightly smaller than the first conductive layer 8.

Then, a second impurity is implanted to form the n− region 10n− in the first semiconductor layer 10.

In the present embodiment, P (phosphorus) was implanted to 3 E13/cm² at 55 keV as the impurity such that the sheet resistance of the n− region 10n− became 10 k to 200 kΩ/□. Then, the resist 24 was removed.

Next, as shown in FIG. 18(b), patterning is performed using the resist 24 in order to form the n+ region 10n+ of the second photodiode 26 and the N-channel TFT element 20. A third impurity is implanted into the first semiconductor layer 10 to form the n+ region 10n+. The channel region 10c is formed at the same time.

In the present embodiment, P (phosphorus) was implanted to 5 E15/cm² at 45 keV as the third impurity such that the sheet resistance of the n+ region 10n+ became 200 to 10 kΩ/□. Then, the resist 24 was removed.

Then, as shown in FIG. 18(c), the resist 24 is patterned again in order to form the p+ region 10p+ of the second photodiode 26 and the P-channel TFT element 27. A sixth impurity is implanted into the first semiconductor layer 10 to form the p+ region 10p+.

In the present embodiment, B (boron) was implanted to 9 E15/cm² at 60 keV as the sixth impurity such that the sheet resistance of the p+ region 10p+ became 200 to 10 kΩ/□. Then, the resist 24 and the second insulating film 11 were removed. Then, the first semiconductor layer 10 was patterned.

Finally, as shown in FIG. 18(d), the liquid crystal display device 1b having a liquid crystal display panel 2b that has the photodiode 19 (not shown in the figure), the second photodiode 26, the N-channel TFT elements 20 and 21 (not shown in the figure), and the P-channel TFT element 27 was manufactured using the manufacturing process of the liquid crystal display device described in Embodiment 1.

Here, because the second photodiode 26 is a PIN photodiode of a lateral configuration, the SiGe layer is not formed. Therefore, the third insulating film 12 is not removed.

Further, a SiGe photodiode in which an intrinsic SiGe layer and an n+ SiGe layer are laminated in this order may be formed on the p+ region 10p+ of the first semiconductor layer 10.

In the liquid crystal display device 1b of the present embodiment, the SiGe photodiode of a multilayer configuration that can sense light near a wavelength of 850 nm (infrared region) and the PIN photodiode of a lateral configuration that can sense visible light are provided at the same time.

Therefore, the SiGe photodiode can sense light near a wavelength of 850 nm (infrared region), thereby making the liquid crystal display device 1b function as a touch panel. The PIN photodiode of a lateral configuration can sense visible light, thereby making the liquid crystal display device 1b function as a scanner.

Furthermore, the liquid crystal display device 1b of the present embodiment can have the N-channel TFT element and the P-channel TFT element at the same time. As a result, a CMOS circuit can be also formed.

Therefore, the liquid crystal display device 1b that consumes less power and that can have a narrow frame can be achieved because the CMOS circuit can be formed.

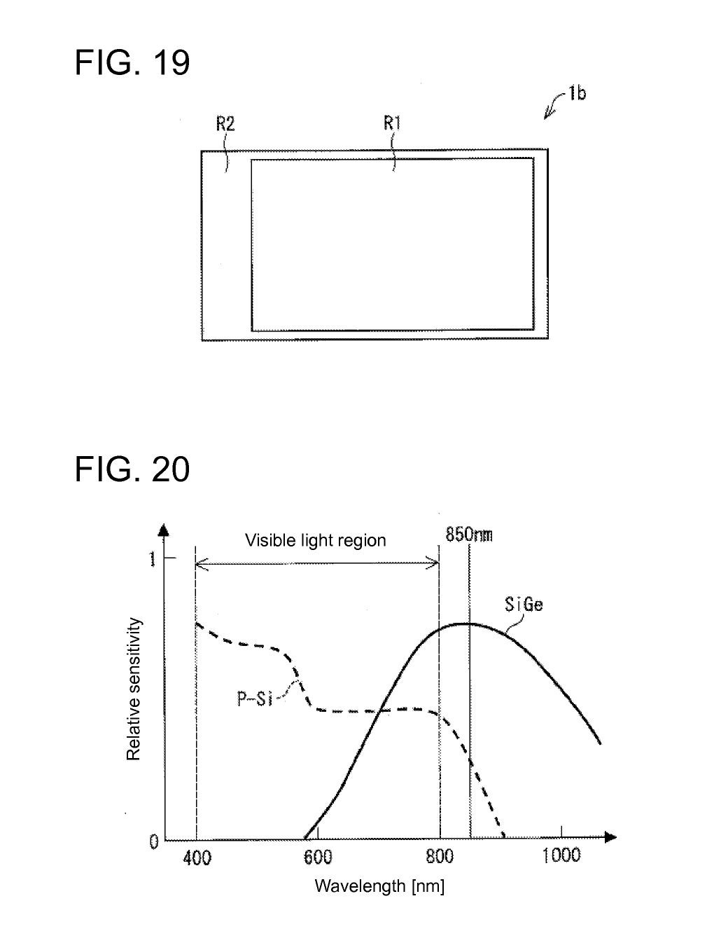

FIG. 19 is a drawing showing a display surface of the liquid crystal display device 1b of the present embodiment.

As shown in FIG. 19, the liquid crystal display device 1b has a display region R1 and a non-display region R2 that is a peripheral portion of the display region R1. Both of the regions R1 and R2 of the liquid crystal display device 1b have two types of photodiodes described above and a CMOS circuit formed of the N-channel TFT element and the P-channel TFT element.

FIG. 20 is a drawing showing spectral sensitivity characteristics of the two types of photodiodes 19 and 26 provided in the liquid crystal display device 1b of the present embodiment.

As shown in the figure, the SiGe photodiode 19 can sense light near a wavelength of 850 nm (infrared region). The PIN photodiode 26 of a lateral configuration can sense visible light.

As described above, the liquid crystal display device 1b of the present embodiment can have the touch panel function and the scanner function at the same time, and can form the CMOS circuit. As a result, it is possible to achieve the liquid crystal display device 1b that consumes less power and that can have a narrow frame.

In the photodiode of the present invention, the light receiving surface preferably is covered by either one layer of the first semiconductor layer or the third semiconductor layer. The opposite surface of the light receiving surface of the second semiconductor layer preferably is covered by the other one layer of the first semiconductor layer or the third semiconductor layer.

In the photodiode of the present invention, when forming the second semiconductor layer on either one layer of the first semiconductor layer or the third semiconductor layer, the second semiconductor layer preferably is grown by selective growth at a location at which that one of the layers has been formed among a position at which such a one layer has been formed and a position at which such a one layer has not been formed. When forming the other one layer of the first semiconductor layer or the third semiconductor layer on the light receiving surface of the second semiconductor layer, the other one layer preferably is grown by selective growth at a position at which the second semiconductor layer has been formed among a position at which the second semiconductor layer has been formed and a position at which the second semiconductor layer has not been formed

In the photodiode of the present invention, the second semiconductor layer preferably is a semiconductor layer formed of silicon and germanium.

According to this configuration, it is possible to achieve a photodiode in which only the sensitivity to light near a wavelength of 850 nm (infrared region) is increased and the sensitivity to other wavelength regions is suppressed to be low.

In the photodiode of the present invention, the light receiving surface of the second semiconductor layer preferably is formed to have recesses and protrusions.

According to the configuration above, a photodiode in which the spectral sensitivity characteristics are improved further can be achieved.

In the photodiode of the present invention, a transparent conductive layer preferably is formed so as to cover one of the first semiconductor layer and the third semiconductor layer formed on the light receiving surface of the second semiconductor layer. The transparent conductive layer preferably has a portion that does not overlap the second semiconductor layer in a plan view. In the non-overlapping portion, the transparent conductive layer preferably is electrically connected to an external wiring line.

As an electrode for reading out a signal of the photodiode, one of the first semiconductor layer and the third semiconductor layer formed on the light receiving surface of the second semiconductor layer is used. In order to increase the amount of light entering the light receiving surface of the second semiconductor layer, that layer preferably is formed thin.

However, when the one layer is formed thin, the sheet resistance becomes high (approximately several k to MΩ/□), and it may become more difficult to read out the signal of the photodiode.

According to the configuration above, the transparent conductive layer formed so as to cover one of the first semiconductor layer and the third semiconductor layer formed on the light receiving surface of the second semiconductor layer can be used as the electrode for reading out the signal of the photodiode. Because of this, the sheet resistance can be reduced to 1 to several hundred Ω/□ approximately, thereby facilitating reading out of the signal. Furthermore, the one layer can be made thin because of this. As a result, the amount of light entering the light receiving surface of the second semiconductor layer can be increased.

Further, according to the configuration above, the transparent conductive layer has a portion that does not overlap the second semiconductor layer in a plan view. In the non-overlapping portion, the transparent conductive layer is electrically connected to the external wiring line. Therefore, the amount of light entering the light receiving surface of the second semiconductor layer can be increased.

Further, when a transparent pixel electrode or the like is formed above the transparent conductive layer through a transparent insulating layer in a display device and the like, a transparent auxiliary capacitance can be formed. Therefore, the aperture ratio can be increased in the display device.

In the display panel substrate of the present invention, the active element preferably is a thin film transistor, and the channel layer of the thin film transistor preferably is formed of a semiconductor layer that is different from the second semiconductor layer.

According to the configuration above, the channel layer of the thin film transistor is formed of a semiconductor layer that is different from the second semiconductor layer of the photodiode. As a result, the film thickness of the channel layer and the film thickness of the second semiconductor layer can be separately set. Therefore, the optimum film thicknesses for their respective characteristics can be set.

In the display panel substrate of the present invention, a second photodiode having a light receiving surface in which the relative light receiving sensitivity to the respective wavelengths of light has the highest value at a wavelength in a visible light region preferably is formed.

According to the configuration above, the photodiode can sense light near a wavelength of 850 nm (infrared region), thereby functioning as a touch panel, and the second photodiode can sense light of a visible light region, thereby functioning as a scanner.

In the method of manufacturing the photodiode of the present invention, either one layer of the first semiconductor layer or the third semiconductor layer preferably is crystallized before forming the second semiconductor layer on the one layer.

According to the manufacturing method above, either one layer of the first semiconductor layer or the third semiconductor layer is crystallized to have crystallinity.

When forming the second semiconductor layer by selective growth on the one layer, the second semiconductor layer grows by carrying over the crystallinity of the first semiconductor layer, and becomes either polycrystalline or microcrystalline instead of amorphous. Therefore, the spectral sensitivity characteristics with respect to light near a wavelength of 850 nm (infrared region) becomes higher than an amorphous layer.

In the method of manufacturing the photodiode of the present invention, the crystallization preferably is performed in an oxygen atmosphere.

According to the manufacturing method above, either one layer of the first semiconductor layer or the third semiconductor layer is crystallized in the oxygen atmosphere. This way, the ratio of a designated crystal orientation in the one layer can be increased.

When forming the second semiconductor layer by selective growth on the one layer, the crystal orientation of the second semiconductor layer is also aligned with the designated crystal orientation. Therefore, it is possible to reduce variations in spectral sensitivity characteristics of the respective photodiode elements.

In the method of manufacturing the photodiode of the present invention, a surface of one of the first semiconductor layer or the third semiconductor layer preferably is formed to have recesses and protrusions before forming the second semiconductor layer on the one layer.

According to the manufacturing method above, the surface of one of the first semiconductor layer or the third semiconductor layer is formed to have recesses and protrusions. When the second semiconductor layer is formed by selective growth on that layer, the second semiconductor layer also has the recesses and protrusions, and the spectral sensitivity characteristics can be improved.

The present invention is not limited to the respective embodiments described above, and various modifications within the scope set forth in the claims are possible. Embodiments obtained by appropriately combining technical means respectively disclosed in different embodiments are also included in the technical scope of the present invention.

### INDUSTRIAL APPLICABILITY

The present invention can be applied in a photodiode, a display panel substrate, and a display device.

### DESCRIPTION OF REFERENCE CHARACTERS

1, 1a, 1b liquid crystal display devices (display devices)
2, 2a, 2b active matrix substrates (display panel substrates)
5 planar light source device
10 first semiconductor layer
13 second semiconductor layer (light receiving portion)
13a light receiving surface
14 third semiconductor layer
19 photodiode
20, 21 N-channel TFT elements (active elements)
25 transparent conductive layer
26 second photodiode
27 P-channel TFT element (active element)
W width of a light receiving portion in a lengthwise direction

1. A photodiode that has a first semiconductor layer, a second semiconductor layer, and a third semiconductor layer and that generates different amounts of current depending on an amount of light received on a light receiving surface of said second semiconductor layer,
wherein the first semiconductor layer is a semiconductor layer having a relatively high concentration of an N-type impurity,
wherein the second semiconductor layer is either an intrinsic semiconductor layer or a semiconductor layer that has a relatively low impurity concentration,
wherein the third semiconductor layer is a semiconductor layer having a relatively high concentration of a P-type impurity,
wherein one layer among said first semiconductor layer and said third semiconductor layer is formed on the light receiving surface of said second semiconductor layer so as to cover the light receiving surface of said second semiconductor layer at least partially in a plan view,
wherein the other one layer of said first semiconductor layer and said third semiconductor layer is formed on a surface opposite to said light receiving surface of said second semiconductor layer so as to overlap said light receiving surface and said one layer at least partially in a plan view, and
wherein in said second semiconductor layer, a relative light receiving sensitivity to respective wavelengths of light has the highest value at a wavelength in an infrared region.

2. The photodiode according to claim 1, wherein said light receiving surface is covered by the one layer of said first semiconductor layer and said third semiconductor layer, and
wherein the surface opposite to said light receiving surface of said second semiconductor layer is covered by the other one layer of said first semiconductor layer and said third semiconductor layer.

3. The photodiode according to claim 2, wherein to form said second semiconductor layer on said one layer among said first semiconductor layer and said third semiconductor layer, said second semiconductor layer is grown by selective growth from a surface of said one layer, and
wherein to form said other one layer of said first semiconductor layer and said third semiconductor layer on said light receiving surface of said second semiconductor layer, said other one layer is grown by selective growth from a surface of said second semiconductor layer.

4. The photodiode according to claim 1, wherein said second semiconductor layer is a semiconductor layer that is formed of silicon and germanium.

5. The photodiode according to claim 1, wherein the light receiving surface of said second semiconductor layer is formed to have recesses and protrusions.

6. The photodiode according to claim 1, wherein a transparent conductive layer is formed so as to cover said one layer of said first semiconductor layer and said third semiconductor layer formed on the light receiving surface of said second semiconductor layer,
wherein said transparent conductive layer has a portion that does not overlap said second semiconductor layer in a plan view, and
wherein in said portion that does not overlap said second semiconductor layer, said transparent conductive layer is electrically connected to an external wiring line.

7. A display panel substrate, comprising, on a surface of an insulating substrate, the photodiode according to claim 1 and an active element.

8. The display panel substrate according to claim 7, wherein said active element is a thin film transistor, and
wherein a channel layer in said thin film transistor is formed of a semiconductor layer that is different from said second semiconductor layer.

9. The display panel substrate according to claim 7, further comprising a second photodiode having a light receiving surface in which a relative light receiving sensitivity to respective wavelengths of light is at the highest value at a wavelength in a visible light region.

10. A display device, comprising:
the display panel substrate according to claim 7; and
a planar light source device that emits light including infrared light and visible light in a planar shape.

11. A method of manufacturing a photodiode that has a first semiconductor layer that is a semiconductor layer having a relatively high concentration of an N-type impurity, a second semiconductor layer that is either an intrinsic semiconductor layer or a semiconductor layer that has a relatively low impurity concentration, and a third semiconductor layer that is a semiconductor layer having a relatively high concentration of a P-type impurity and that generates different amounts of current depending on an amount of light received on a light receiving surface of said second semiconductor layer,
wherein one layer of said first semiconductor layer and said third semiconductor layer is first formed,
wherein said second semiconductor layer formed on said one layer is formed of a layer in which a relative light receiving sensitivity to respective wavelengths of light has the highest value at a wavelength in an infrared region,
wherein when forming said second semiconductor layer on said one layer, said second semiconductor layer is formed by selective growth from a surface of said one layer,
wherein when forming the other one layer of said first semiconductor layer and said third semiconductor layer on said second semiconductor layer, said other one layer is formed by selective growth from a surface of said second semiconductor layer.

12. The method of manufacturing a photodiode according to claim 11, wherein crystallization of said one layer of said first semiconductor layer and said third semiconductor layer is performed before said second semiconductor layer is formed on said one layer.

13. The method of manufacturing a photodiode according to claim 12, wherein said crystallization is performed in an oxygen atmosphere.

14. The method of manufacturing a photodiode according to claim 11, wherein a surface of said one layer of said first semiconductor layer and said third semiconductor layer is formed to have recesses and protrusions before said second semiconductor layer is formed on said one layer.
